(19) United States
(12) Patent Application Publication
(10) Pub. No.: US 2017/0311411 A1
(43) Pub. Date: Oct. 26, 2017

(54) DEPOSITION-MASK MANUFACTURING METHOD, DEPOSITION MASK, DEPOSITION DEVICE, AND DEPOSITION METHOD

(71) Applicant: Sharp Kabushiki Kaisha, Sakai City (JP)

(72) Inventors: Kazuo TAKIZAWA, Sakai City (JP); Shinichi KAWATO, Sakai City (JP); Manabu NIBOSHI, Sakai City (JP); Yuhki KOBAYASHI, Sakai City (JP)

(73) Assignee: Sharp Kabushiki Kaisha, Sakai City (JP)

(21) Appl. No.: 15/520,480

(22) PCT Filed: Oct. 16, 2015
(86) PCT No.: PCT/JP2015/079335

§ 371 Date: Apr. 20, 2017

(30) Foreign Application Priority Data
Oct. 23, 2014 (JP) 2014-216619

(51) Int. Cl. H05B 33/14; H01L 51/50; H01L 51/00; C23C 16/04; C23C 14/12; H05B 33/10; C23C 14/04

(52) U.S. Cl. CPC H05B 33/14; H05B 33/10; H01L 51/50; C23C 14/04; C23C 16/04; C23C 14/12; H01L 51/0011

(57) ABSTRACT

A method of producing a vapor deposition mask includes the steps of (i) preparing a mixture which contains a resin material and an inorganic filler and (ii) shaping, with use of a reactor which serves as a shaping die, the mixture so that the mask substrate is shaped, the mask substrate containing a resin made of the resin material and the inorganic filler mixed in the resin.

### CROSS-REFERENCE TO RELATED APPLICATIONS

This application is a U.S. National Phase patent application of International Patent Application No. PCT/JP2015/079335, filed Oct. 16, 2015, which claims priority to Japanese Application No. 2014-216619, filed Oct. 23, 2014, each of which is hereby incorporated by reference in the present disclosure in its entirety.

### FIELD OF THE INVENTION

The present invention relates to a method of producing a vapor deposition mask, a vapor deposition mask, a vapor deposition device, and a method of vapor deposition.

### BACKGROUND OF THE INVENTION

In recent years, flat panel displays have been applied to various products and fields. This has led to a demand for a flat panel display that is larger in size, achieves higher image quality, and consumes less power.

Under the circumstances, an electro luminescence (EL) display device that includes an EL element using an EL of an organic or inorganic material has drawn great attention as an all-solid-state flat panel display which is excellent in, for example, low voltage driving, high speed response, and self-emitting property.

In order for full color display to be achieved, an EL display device includes a light emitting layer that emits light having an intended color in accordance with a plurality of sub-pixels which constitute a pixel.

A pattern of such a light emitting layer is formed by, for example, a vacuum vapor deposition method using a vapor deposition mask, which is also referred to as a shadow mask.

In order to realize a high-definition EL display device, it is necessary to vapor-deposit vapor deposition particles to a film formation target substrate 200 with high accuracy. Accordingly, a vapor deposition mask needs to be provided with openings with high accuracy.

Conventionally, a metal mask has been used as a typical vapor deposition mask. Such a metal mask is typically made of a metal mask substrate, having openings with a given pattern, which is produced by processing a thin metal plate. The mask substrate is typically used as a vapor deposition mask while being fixed to a support, such as a mask frame.

However, a current metal processing technique has difficulty in forming openings with accuracy in a metal plate. Furthermore, in a case where a metal mask is employed as a vapor deposition mask, it becomes difficult to form a vapor-deposited film pattern with high definition due to, for example, displacement and warping which are caused by heat expansion of a metal plate.

In a case where a mask which is made solely of metal is employed as a vapor deposition mask, the vapor deposition mask increases in mass as it increases in size. This causes an increase in total mass of the vapor deposition mask including a support such as a mask frame, and consequently brings about obstacles to handling.

Under the circumstances, in order to achieve a reduction in weight and an improvement in accuracy of openings, there has been proposed a complex vapor deposition mask whose mask substrate (mask base material), which constitutes a vapor deposition mask, is partially made of resin.

For example, Patent Literature 1 discloses a vapor deposition mask produced by distributing, on a surface of one side of or inside of a resin film having openings, a plurality of metal flakes in an insular manner.

According to Patent Literature 1, a vapor deposition mask is produced as follows. That is, a photosensitive material is applied to a surface of one side of a resin film, and a plurality of holes are randomly developed by exposing a resultant photosensitive resin to light. Subsequently, inner surfaces of the respective plurality of holes are plated with a metal film, and metal flakes, made of the metal film, are distributed on the film in an insular manner by peeling off the photosensitive resin. After that, a resultant mask member is irradiated with laser light while the mask member is in close contact with a reference substrate, on which a reference pattern is formed. As such, a vapor deposition mask having openings corresponding to the reference pattern is produced.

### CITATION LIST

Japanese Patent Application Publication Tokukai No. 2013-173968 (Sep. 5, 2013)

### SUMMARY OF THE INVENTION

For example, laser processing makes it possible to form, in a resin, openings with high accuracy. Furthermore, in a case where a mask substrate is partially made of resin, it is possible to achieve a reduction in weight of a vapor deposition mask. As such, it is possible to improve accuracy of a vapor-deposited film pattern by using, during vapor deposition, a vapor deposition mask whose mask substrate is partially made of resin.

According to Patent Literature 1, however, a complex vapor deposition mask in which a metal layer and a resin layer are laminated is formed by plating, in an insular manner, a surface of a resin film with metal flakes which are made of a metal film.

Since such a conventional complex vapor deposition mask whose mask substrate is partially made of resin has a structure in which a metal layer and a resin layer are laminated, the materials are not mixed with each other. This can cause the layers to peel off of each other. Particularly in a case where (i) a metal layer is made of a magnetic metal and (ii) a vapor deposition mask is held by magnetic force, force is unevenly applied to the vapor deposition mask because the magnetic force, which holds the layer made of the magnetic metal, is not directly applied to a resin layer. This causes a phenomenon such as deflecting and/or peeling of the resin layer of the vapor deposition mask, leading to a failure of a vapor-deposited pattern and/or a damage to the vapor deposition mask.

Furthermore, since a conventional complex vapor deposition mask has a structure in which a metal layer and a resin layer are laminated as has been discussed above, such a mask requires (i) a step of forming a metal layer on a resin layer through, for example, plating or vapor deposition as disclosed in Patent Literature 1 or (ii) a step of forming a resin layer on a metal layer through, for example, spin coating.

As such, in order to produce a conventional complex vapor deposition mask, it is necessary to form one of laminate layers and then form the other of the laminate layers. This causes an increase in number of production steps and consequently causes an increase in defect due to integration of percent defectives in the respective production steps. Particularly in a case where a failure such as peeling of a layer is caused in a post-process, it is necessary to restart formation of a vapor deposition mask from the beginning.

Particularly, according to Patent Literature 1, the mask member and the reference substrate are brought into close contact by causing, while openings are being formed in the mask member, metal flakes provided on the mask substrate to be attracted to a magnetic force chuck. In so doing, a force is unevenly applied to the resin member, which force can consequently cause peeling of the layers.

The present invention has been attained to address the above problem, and an objective of the present invention is to provide (i) a method of producing a vapor deposition mask in which a vapor-deposited film pattern is formed with high definition and materials hardly separate from each other, (ii) such a vapor deposition mask, and (iii) a vapor deposition device. A further objective of the present invention is to provide a method of vapor deposition which makes it possible to form a vapor-deposited film pattern with high definition.

In order to attain the above objective, a method of producing a vapor deposition mask in accordance with an aspect of the present invention is a method of producing a vapor deposition mask including a mask substrate having openings, each of which causes vapor deposition particles to pass therethrough, the method including the steps of: (a) preparing a mixture which contains a resin material and an inorganic filler; and (b) shaping, with use of a shaping die, the mixture so that the mask substrate is shaped, the mask substrate containing (i) a resin made of the resin material and (ii) the inorganic filler mixed in the resin.

In order to attain the above objective, a vapor deposition mask in accordance with an aspect of the present invention includes: a mask substrate having openings, each of which causes vapor deposition particles to pass therethrough, the mask substrate containing a resin and an inorganic filler mixed in the resin.

In order to attain the above objective, a vapor deposition device in accordance with an aspect of the present invention includes: a vapor deposition mask in accordance with an aspect of the present invention; and a vapor deposition source configured to emit vapor deposition particles toward the openings of the vapor deposition mask.

In order to attain the above objective, a method of vapor deposition in accordance with an aspect of the present invention is a method of vapor-depositing a film, having a given pattern, on a film formation target substrate by using a vapor deposition mask in accordance with an aspect of the present invention, the method including the steps of: (a) fixing the film formation target substrate and the vapor deposition mask in a state where the film formation target substrate and the vapor deposition mask are in contact with each other and providing a vapor deposition source, which is configured to emit vapor deposition particles, so that the vapor deposition source is located on an opposite side to a side of the vapor deposition mask on which side the film formation target substrate is located; and (b) depositing the vapor deposition particles on the film formation target substrate via the openings of the vapor deposition mask while the film formation target substrate and the vapor deposition mask are being in contact with each other.

An aspect of the present invention makes it possible to provide (i) a method of producing a vapor deposition mask in which a vapor-deposited film pattern is formed with high definition and materials hardly separate from each other, (ii) such a vapor deposition mask, and (iii) a vapor deposition device. Another aspect of the present invention makes it possible to provide a method of vapor deposition which makes it possible to form a vapor-deposited film pattern with high definition.

### BRIEF DESCRIPTION OF THE DRAWINGS

Each of (a) through (c) of FIG. 1 is a view schematically illustrating a method of producing a vapor deposition mask in accordance with Embodiment 1 of the present invention.

Each of (a) and (b) of FIG. 2 is a view illustrating a step of producing a vapor deposition mask which includes a mask frame in accordance with Embodiment 1 of the present invention.

FIG. 3 is a view illustrating an example schematic configuration of a vapor deposition device which includes a vapor deposition mask in accordance with Embodiment 1 of the present invention.

FIG. 4 is a plan view illustrating a schematic configuration of a main part of a mask production device, together with a mask substrate, in accordance with Embodiment 2 of the present invention.

(a) through (d) of FIG. 5 are cross-sectional views illustrating main parts of sequential steps of producing a vapor deposition mask in accordance with Embodiment 2 of the present invention.

(a) of FIG. 6 is a plan view illustrating a schematic configuration of a main part of a mask production device in accordance with Embodiment 3 of the present invention. (b) of FIG. 6 is a cross-sectional view illustrating the schematic configuration of the main part of the mask production device, together with a mask substrate which is in a mask substrate shaping step, in accordance with Embodiment 3 of the present invention.

(a) of FIG. 7 is a plan view illustrating a schematic configuration of a main part of a mask production device, together with a mask substrate which is in a mask substrate shaping step, in accordance with Embodiment 4 of the present invention. (b) of FIG. 7 is a cross-sectional view illustrating the schematic configuration of the main part of each of the mask production device and the mask substrate illustrated in (a) of FIG. 7. Each of (c) and (d) of FIG. 7 is an enlarged view illustrating an example schematic configuration of a main part, in a region R illustrated in (b) of FIG. 7, of each of the mask production device and the mask substrate.

(a) of FIG. 8 is a plan view illustrating a schematic configuration of a main part of a mask production device, together with a mask substrate which is in a mask substrate shaping step, in accordance with Embodiment 5 of the present invention. (b) of FIG. 8 is a cross-sectional view illustrating the schematic configuration of the main part of each of the mask production device and the mask substrate illustrated in (a) of FIG. 8.

(a) of FIG. 9 is a plan view illustrating a schematic configuration of a main part of a mask production device, together with a mask substrate which is in a mask substrate shaping step, in accordance with Embodiment 6 of the present invention. (b) is a cross-sectional view illustrating the schematic configuration of the main part of the mask production device and the mask substrate illustrated in (a) of FIG. 9.

### DETAILED DESCRIPTION OF THE INVENTION

The following description will discuss embodiments of the present invention.

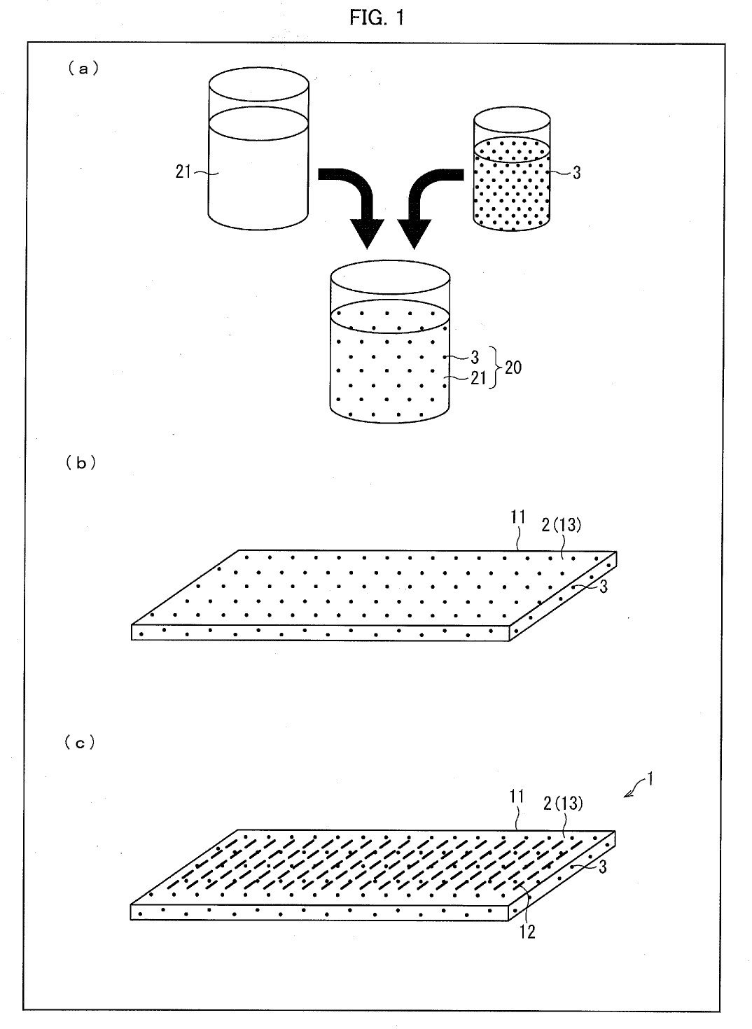

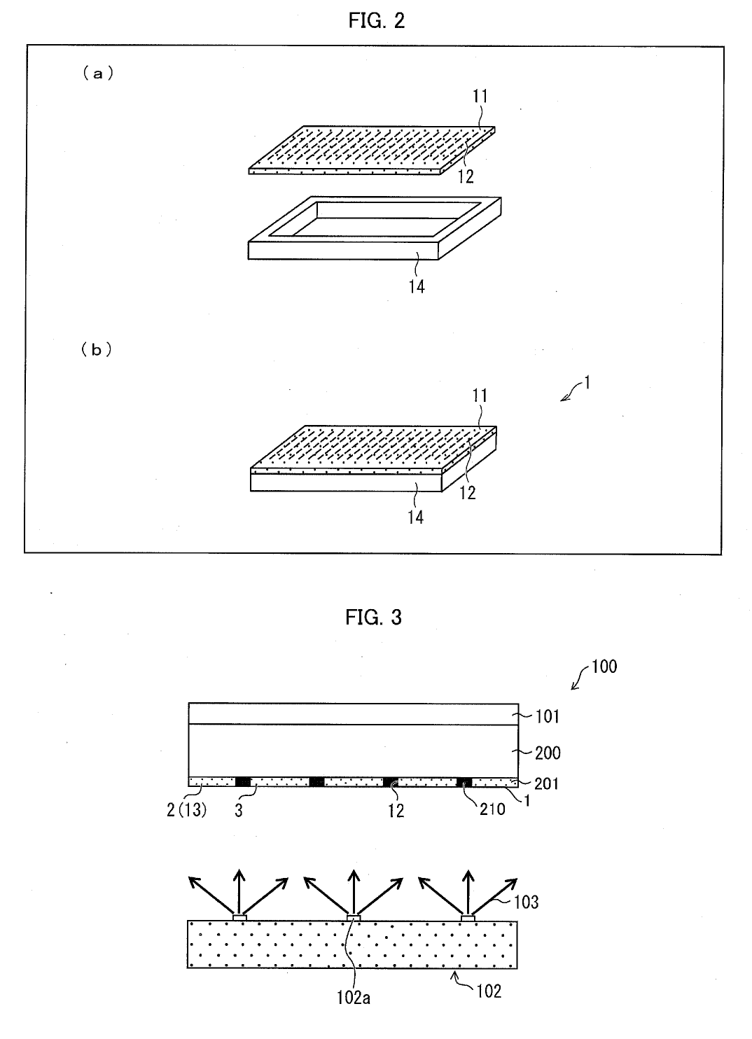

The following description will discuss Embodiment 1 of the present invention with reference to (a) through (c) of FIG. 1 and FIG. 3.

Each of (a) through (c) of FIG. 1 is a view schematically illustrating a method of producing a vapor deposition mask in accordance with Embodiment 1.

A schematic configuration of a vapor deposition mask 1 in accordance with Embodiment 1 will be first discussed below.

<Schematic Configuration of Vapor Deposition Mask 1>

The vapor deposition mask 1 in accordance with Embodiment 1 is a resin mask which contains an inorganic filler (see (c) of FIG. 1). The vapor deposition mask 1 includes a thin plate mask substrate 11 (mask substrate) which is made up of a resin layer 2 in which inorganic particles 3 are mixed as the inorganic filler (inorganic mixture, inorganic additive). The mask substrate 11 has openings 12 (mask openings).

The vapor deposition mask 1 is incorporated in a vapor deposition device 100 (see FIG. 3). The vapor deposition mask 1 is a mask for use in vapor deposition through which a vapor deposition film 210 (vapor-deposited film pattern), having a given pattern, is formed on a film formation target surface 201 of a film formation target substrate 200.

The mask substrate 11 (i) is used, as it is, as a vapor deposition mask 1 or (ii) is used while being fixed to a support such as a mask frame 14 (see (a) and (b) of FIG. 2).

As discussed above, a main surface of the vapor deposition mask 1, i.e., a main surface of the mask substrate 11, has through-holes as the openings 12. The through-holes allow vapor deposition particles, which cause a vapor-deposited film pattern to be formed, to pass therethrough during vapor deposition (i.e., during forming a vapor-deposited film pattern). This causes an intended vapor-deposited film pattern to be formed on the film formation target substrate 200.

Each of the openings 12 has a shape (i) which is identical (substantially identical) to a vapor-deposited film pattern, which is to be formed on a surface of the film formation target substrate 200 or (ii) which corresponds to at least a part of the vapor-deposited film pattern.

Note that, for example, the vapor deposition mask 1 is used to form, on the film formation target substrate 200, a vapor-deposited film pattern by use of various materials, such as an organic material or an inorganic material, an electrode material, a dielectric material, and an insulation material, which constitute an EL layer (organic layer or inorganic layer) which serves as a light emitting layer or the like in an organic EL device or an inorganic EL device. (c) of FIG. 1 illustrates an example case where the main surface of the vapor deposition mask 1 has a plurality of rectangular openings 12 which are arranged in a two-dimensional (matrix) manner. However, a shape and an arrangement of the openings 12 are not limited as such. The shape and the arrangement of the openings 12 can be set as appropriate in accordance with, for example, intended use and/or a method of vapor deposition which depends on a type of the vapor deposition film so that a desired vapor-deposited film pattern can be obtained.

That is, the shape of the openings 12 are changed not only in accordance with the intended use of the vapor deposition film, but also in accordance with, for example, whether to make (i) a scanning vapor deposition in which a vapor deposition is made while the vapor deposition mask 1 and the film formation target substrate 200 are being moved relatively to each other, (ii) a step vapor deposition in which a first vapor deposition is made while the vapor deposition mask 1 is being aligned with the film formation target substrate 200, and then a second vapor deposition is made after a position of the vapor deposition mask 1 is shifted with respect to the film formation target substrate 200, or (iii) a fixed vapor deposition in which a vapor deposition is made while the vapor deposition mask 1 and the film formation target substrate 200 are being contacted with and fixed to each other.

As such, the shape and arrangement of the openings 12 are not limited to the above shape and arrangement. Alternatively, the openings 12 can be formed in, for example, a slot shape. Furthermore, it is only necessary to provide at least one opening 12. As discussed above, (c) of FIG. 1 illustrates an example case where a plurality of openings 12 are arranged in a two-dimensional manner. Alternatively, (i) the plurality of openings 12 can be arranged in a one-dimensional manner or (ii) a single opening 12 can be provided instead of the plurality of openings 12.

An EL display panel is produced by, for example, (i) forming one of a positive electrode and a negative electrode on a semiconductor substrate such as a TFT substrate made of a glass substrate or the like, (ii) vapor-depositing, on the one of the positive electrode and the negative electrode via the vapor deposition mask 1, vapor deposition particles each of which is made of an organic material or an inorganic material so as to form a light emitting layer, and then (iii) forming the other of the positive electrode and the negative electrode on the vapor-deposited film (i.e., light emitting layer) thus obtained.

In the above case, the openings 12 are provided for respective sub-pixels on the film formation target substrate 200 so that the vapor deposition particles do not stick to a region, of the film formation target substrate 200, other than regions for target sub-pixels. This causes only the vapor deposition particles which have passed the openings 12 to reach the film formation target substrate 200. This ultimately causes a vapor deposition film, having a given pattern which corresponds to the shape of the openings 12, to be formed, for each sub-pixel, on the film formation target substrate 200.

Note that, when the vapor deposition mask 1 is viewed from above, its size is not particularly limited and can be set as appropriate in accordance with, for example, a method of vapor deposition or a size of the film formation target substrate 200. Similarly, when the openings 12 are viewed from above, their sizes and shapes are not particularly limited and can be set as appropriate in accordance with, for example, the application of the vapor deposition film so that an intended vapor-deposited film pattern will be obtained. Such conditions can be set as with, for example, a conventional vapor deposition mask.

A thickness of the vapor deposition mask 1 can be set as appropriate in accordance with, for example, the size of and a weight of the vapor deposition mask 1, when viewed from above. Note, however, that the thickness of the vapor deposition mask 1, specifically a thickness of the mask substrate 11, is preferably as small as possible. A reduction in thickness of the mask substrate 11 makes it possible to restrain the occurrence of a vapor deposition shadow which causes a non-deposited part in which a thickness of a vapor-deposited film is smaller than an intended thickness. It is therefore preferable that the mask substrate 11 has a thickness of approximately 10 μm to 30 μm. Note, however, that in a case where the mask substrate 11 is excessively thin, the vapor deposition mask 1 has a reduced strength. It is therefore preferable to set the thickness of the mask substrate 11 within a range in which a sufficient strength can be secured.

With regard to the vapor deposition mask 1, i.e., the mask substrate 11 in accordance with Embodiment 1, it is highly important that it contains, in a single layer, both (i) a resin 13 which is an organic substance constituting the resin layer 2 and (ii) an inorganic particle 3 which is an inorganic substance.

That is, the vapor deposition mask 1 is a complex mask which contains the resin 13 and the inorganic particles 3 which are mixed in the resin 13. Accordingly, the vapor deposition mask 1 differs from a conventional composite mask in that the inorganic substance does not form a layer such as a metal flake made of an inorganic substance. The vapor deposition mask 1 therefore does not have a configuration in which a resin layer and a layer which is made of an inorganic substance are laminated as respective separate layers.

A resin (plastic material) can be employed as the resin 13, which resin is similar to a resin employed as a material of a resin mask used in (i) a vapor deposition mask made of a publicly-known resin or (ii) a vapor deposition mask in which the resin mask and a metal mask are laminated.

For example, polyimide is suitable for a material of the vapor deposition mask 1 because (i) it has a high glass transition temperature of not lower than 400° C., (ii) it is rigid and robust, and (iii) it has a high heat resistance.

Note, however, that the resin 13 is not limited to the above example, provided that it is not plastically deformed at a temperature at which the vapor deposition particles are vapor-deposited by use of the vapor deposition mask 1. As such, the resin 13 is not limited to a curable resin. A thermoplastic resin can also be employed as the resin 13, provided that it has a softening point (heat deformation temperature) higher than the vapor deposition temperature at which the vapor deposition particles are vapor-deposited by use of the vapor deposition mask 1.

Examples of the curable resin include a thermosetting resin and a photo-curable resin.

As discussed above, the resin 13 is not particularly limited, provided that it is not plastically-deformed at the vapor deposition temperature at which the vapor deposition particles are vapor-deposited by use of the vapor deposition mask 1. It is, however, preferable to employ, as the resin 13, a lightweight material (i) which has a small rate of change in dimension for heating and ageing and (ii) from which high-definition openings 12 can be formed through laser processing or the like.

Examples of the resin 13 include a polyimide resin, a polyamide resin, a polyamide-imide resin, a polyester resin, a polyethylene resin, a polyvinyl alcohol resin, a polypropylene resin, a polycarbonate resin, a polystyrene resin, a polyacrylonitrile resin, and the like.

Examples of a suitable material of the inorganic particles 3 include a metal material, a magnetic material, and the like.

Examples of metal particles made of the metal material (i.e., metal) include magnetic metal particles, made of a magnetic metal material such as iron, nickel, invar (alloy of iron and nickel), or stainless steel SUS430, which have a magnetic property.

Note, however, that the metal particles are not limited to the magnetic metal particles. Examples of the metal particles also include non-magnetic metal particles made of a non-magnetic metal material which has no magnetic property.

Magnetic particles made of the magnetic material (i.e., magnetic substance) are not limited to the above magnetic metal particles. Examples of the magnetic particles include Fe₂O₃ particles, Fe₃O₄ particles, magnetic ceramic particles, including iron oxide particles which are made of a magnetic ceramic material such as ferrite, and magnetic particles composed of inorganic nano-fine particles modified with organic molecules.

Particles which are obtained by coating surfaces of base particles (core particles) with the metal material or the magnetic material can also be employed as the inorganic particles 3.

The inorganic nano-fine particles modified by organic molecules can be obtained by, for example, (i) pretreating inorganic nanoparticles in a subcritical water at a high temperature under a high pressure and (ii) reacting the inorganic nanoparticles with an organic modifier in a supercritical water at a high temperature under a high pressure (see, for example, Patent Literature 2).

Examples of the inorganic nanoparticles include metal oxide nanoparticles and metal hydroxide nanoparticles, which can be bonded to the organic modifier (ligand) through a covalent bond or a bond which is as strong as the covalent bond, and the like. Examples of such inorganic nanoparticles include metal oxide of and metal hydroxide of a metal selected from a group consisting preferably of Group 3 elements through Group 17 elements of the periodic table, more preferably of Group 11 metals, Group 12 metals, Group 3 metals (including lanthanoid and actinoid), Group 13 metals, Group 4 metals, Group 14 metals, Group 5 metals, Group 15 metals, Group 16 metals, Group 17 metals, and transition metals of Group 6 through Group 10, and the like.

Examples of the organic modifier include organic phosphorous compounds, such as phosphoric acid ester, phosphorous acid ester, phosphonic acid ester, phosphonous acid ester, phosphonic acid ester, phosphinous acid ester, phosphine, and phosphine oxide, carboxylic acids, amines, alcohols, aldehydes, ketones, esters, amides, oximes, phosgene, enamines, amino acids, peptides, sugars, sulfur analogues such as thiols and thiocarboxylic acids, and the like.

A particle diameter of the inorganic particles 3 is not particularly limited. However, the inorganic particles 3 are preferably nanoparticles having an average particle diameter (weight average particle diameter) of smaller than 1 μm (submicron order).

With the configuration of the mask substrate 11, as has been discussed, the inorganic particles 3 are mixed in the resin layer 2. It is therefore possible for the mask substrate 11 to have stiffness. This allows an enhancement in strength of the vapor deposition mask 1.

Particularly in a case where the magnetic particles are employed as the inorganic particles 3, it is possible to attract and hold, during the vapor deposition, the vapor deposition mask 1 by magnetic force generated by a magnetic force generating source 101 (see FIG. 3) such as a magnet (e.g., magnet plate) or an electric magnet. For example, in a case where the magnetic force generating source 101 is provided on an opposite side to a side of the film formation target substrate 200 on which side the vapor deposition mask 1 is provided, the magnetic force generated by the magnetic force generating source 101 attracts the vapor deposition mask 1 together with the film formation target substrate 200. This makes it possible to fix the film formation target substrate 200 and the vapor deposition mask 1 while they are in close contact with each other.

Note that a mixing ratio of the inorganic particles 3 contained in the resin layer 2 is not particularly limited, and can be freely adjusted in accordance with materials to be used, a combination of such materials, and/or the like so that an intended function can be carried out. In a case where the inorganic particles 3 are, for example, Fe₃O₄ particles which are respective magnetic particles, it is preferable to mix the inorganic particles 3 and the resin 13 so that the inorganic particles 3 account for not less than 20 wt % of an entire vapor deposition mask which has been subjected to shaping.

It is possible to adjust physical properties such as a magnetic property, by thus adjusting, for example, a kind of, and/or a particle diameter of the inorganic particles 3, and/or a mixing ratio of the inorganic particles 3 contained in the resin layer 2.

Note that in a case where inorganic nano-fine particles are employed as the inorganic particles 3, such inorganic nano-fine particles are dissolved or dispersed in the resin 13. Particularly in a case where inorganic nano-fine particles modified with organic molecules are employed as the inorganic particles 3 as discussed above, it is possible to (i) improve solubility of the inorganic particles 3 in the resin 13 and (ii) increase an amount of the inorganic particles 3 mixed in the resin 13.

<Method of Producing Vapor Deposition Mask 1>

The following description will discuss a method of producing the vapor deposition mask 1 in accordance with Embodiment 1. Note that dimensions, materials, and the like of respective constituent elements discussed below are illustrative only, and the scope of the present invention should not be narrowly construed based thereon.

In a production process of the vapor deposition mask 1, (i) a mixture 20 containing a resin material 21 by which the resin layer 2 is formed and (ii) the inorganic particles 3 are prepared as a raw material (mixture preparing step). Then, the mask substrate 11 is formed by processing the mixture 20 into a thin plate (processing step).

In the processing step, the vapor deposition mask 1 is produced by (i) processing the mixture 20 so as to shape a thin plate mask substrate 11 (thin plate member, plate member) in which no opening 12 has been formed (shaping step) (see (b) of FIG. 1) and then (ii) forming the openings 12 in the thin plate mask substrate 11 (opening forming step) (see (c) of FIG. 1).

Note that the mixture 20 can be a liquid or a solid. The mixture 20 is preferably a liquid (i.e., a mixed solution), from the perspective that the inorganic particles 3 have miscibility (e.g., dispersibility or solubility).

In a case where, for example, the resin 13 is a thermoplastic resin or the like, it is possible to employ, as the resin material 21, for example, a granulated (pellet or powder) resin 13, depending on a kind of the resin 13.

It is, however, possible to mix the resin material 21 with the inorganic particles 3 more evenly, by employing a liquid resin material 21 as the resin material 21. As such, in the mixture preparing step, it is preferable to, for example, (i) employ a liquid resin material as the resin material 21 by which the resin layer 2 is formed and (ii) disperse or dissolve the inorganic particles 3 in the resin material 21. Note that, as has been discussed, it is possible to freely adjust an amount of the inorganic particles 3 to be mixed in the resin material 21.

Note that the following description will mainly discuss an example in which a mixed solution, which contains (i) the resin material 21 by which the resin layer 2 is formed and (ii) the inorganic particles 3, is employed as the mixture 20 which contains (a) the resin material 21 by which the resin layer 2 is formed and (b) the inorganic particles 3.

In a case where a mixed solution is prepared as the mixture 20, a liquid resin material 21 is employed as the resin material 21 so as to be mixed with the inorganic particles 3, in the mixture preparing step.

Examples of the resin material 21 include a liquid curable resin, a liquid resin precursor, and a molten thermoplastic resin.

In order for the resin material 21 to be made in liquid form or in order for a viscosity of the resin material to be adjusted, the resin material 21 can be obtained by (i) dissolving the resin 13 or a resin precursor, which is to be a precursor of the resin 13, in a solvent such as an organic solvent or (ii) dispersing the resin 13 or the resin precursor in a dispersion medium. That is, the mixed solution (i.e., the mixture 20) can be a solution or a dispersion liquid.

In a case where the resin precursor is employed as the resin material 21, the resin precursor is mixed with the inorganic particles 3. Then, the resin precursor is polymerized while a mixture of the resin precursor and the inorganic particles 3 are being processed (shaped) to have a shape of thin plate. This allows the inorganic particles 3 to be bonded to each other via the resin 13.

For example, polyimide, particularly aromatic polyimide, which is suitable as a material of the vapor deposition mask 1 because of its rigidity, rigidity, and high heat resistance, is insoluble and infusible. As such, in a case where, for example, polyimide is employed as the resin 13, it is necessary to (i) prepare the mask substrate 11 by mixing polyamide acid, which is a polyimide precursor, with the inorganic particles 3 and (ii) make a conversion of the polyamide acid into polyimide.

The polyamide acid can be dissolved in, for example, an organic solvent (organic solvent agent) such as toluene. Cyclodehydration (imidization) reaction is carried out so that a conversion of the polyamide acid into polyimide is made, in a case where, for example, the mask substrate 11 is shaped with use of a shaping die for forming the mask substrate while a toluene solution containing polyamide acid is being mixed with a toluene dispersion liquid containing the inorganic particles 3 so that the polyamide acid and the inorganic particles 3 are evenly dispersed.

The conversion of the polyamide acid into polyimide can be made, by (i) heating the polyamide acid at a temperature of 200° C. or higher, (ii) carrying out a chemical imidization with the use of an imidization catalyst, or (iii) a combination of the above (i) and (ii). The imidization catalyst is not particularly limited. Examples of the imidization catalyst include publicly-known imidization catalysts such as a nitrogen-containing heterocyclic compound, an N-oxide compound of such a nitrogen-containing heterocyclic compound, an amino-acid compound, an aromatic hydrocarbon compound having a hydroxyl group, and an aromatic heterocyclic compound. During imidization reaction, it is also possible to use, for example, carboxylic acid anhydride as a dehydration agent.

Depending on the kind of the resin 13 which constitutes the resin layer 2, the resin material 21 can contain a solvent, a catalyst, a dehydration agent, a curing agent, or the like. The inorganic particles 3 can be directly mixed in the resin material 21. Alternatively, the inorganic particles 3 can be mixed with the resin material 21 while being dispersed in a dispersion medium. Specifically, inorganic particles 3 can be mixed with the resin material 21 while being dispersed in, for example, a solvent agent such as the solvent discussed above.

Such a solvent is not particularly limited, provided that it can at least dissolve the resin 13 or a resin precursor which is to be a precursor of the resin 13. In a case of dispersing the resin 13 in a dispersion medium, the dispersion medium is not particularly limited, provided that it can disperse the resin 13 and the inorganic particles 3.

In a case where the inorganic particles 3 is mixed with the resin material 21 while being dispersed in a dispersion medium, it is preferable to employ, as the dispersion medium, (i) a solvent which dissolves or disperses the resin 13 or the resin precursor, (ii) a solvent equivalent to a dispersion liquid, or (iii) a dispersion liquid.

The resin material 21 and the inorganic particles 3 can be mixed by stirring them. A mixing machine which is used to mix the resin material 21 with the inorganic particles 3 is not particularly limited, and can be selected as appropriate in accordance with, for example, (i) whether the mixture 20 is a liquid or a solid, (ii) a composition, (iii) a viscosity, and/or, (iv) an amount of the mixture 20. Examples of the mixing machine include various mixing machines available in the market.

Note that, as has been discussed, it is preferable to evenly disperse or dissolve, in the mixture preparing step, the inorganic particles 3 in the resin material 21. In a case where the inorganic particles 3 are magnetic particles or contain magnetic particles, it is preferable to prevent aggregation of the inorganic particles 3 by preventing the magnetic particles from sticking to a stirring tool. As such, it is preferable not to use, as the mixing machine which is used to mix the resin material 21 with the inorganic particles 3, a machine, such as a magnetic stirrer, which stirs by use of magnetic force. According to such a case, the mixture 20 can be mixed with use of, for example, a stirrer like a case where (i) the mixture 20 is, for example, a mixed solution. In a case where a stirrer is employed as the mixing machine, it is preferable to stir the mixture 20 with a plastic stirrer.

In a case where a mixed solution is employed as the mixture 20 so that the inorganic particles 3 are prevented from aggregating, such a mixed solution can contain a flocculant. The flocculant is not limited to a particular kind, and can be selected as appropriate in accordance with, for example, a composition of the mixed solution.

In addition to the inorganic particles 3, the mixture 20 can contain, as an inorganic filler (inorganic mixture, inorganic additive), a coupling agent such as a silane coupling agent. By coupling the inorganic particles 3 and the resin 13 together, it is possible to further prevent the inorganic particles 3 from separating from the resin 13. That is, the mask substrate 11 can be configured such that the inorganic particles 3 are bonded to each other by the resin 13 which is coupled with the inorganic particles 3.

The coupling agent is not particularly limited. A publicly-known coupling agent can be employed as the coupling agent. A kind of and a used amount of the coupling agent can be selected as appropriate in accordance with kinds of the resin 13 and the inorganic particles 3, which are to be used, so that the resin 13 and the inorganic particles 3 are coupled together.

In the processing step of shaping the mask substrate 11, any of various publicly-known shaping methods can be employed.

Note that it is possible to employ, as a shaping condition of the mask substrate 11, a shaping condition identical to that of an organic material (i.e., the shaping condition of the resin 13). That is, the mask substrate 11 can be shaped into a thin plate under a condition identical to that of the organic material which does not contain any inorganic material (i.e., inorganic particles 3).

The shaping of the mask substrate 11 can be carried out by use of any of various shaping methods such as a cast molding method, a solution cast method, a vacuum-pressure shaping method, a powder shaping method, and a plastic processing method. Such a method can be selected in accordance with, for example, the kind of the resin 13.

Examples of a mask production device (vapor deposition mask production device), which is used to produce the vapor deposition mask 1, include (i) a mask production device equivalent to a conventional mask production device which includes a shaping die for shaping a mask substrate and (ii) a mask production device which will be later discussed in a later discussed embodiment.

Shaping temperatures (e.g., polymerization temperature and curing temperature) and shaping times (e.g., a polymerization time and a curing time) in the shaping step can be set as appropriate in accordance with the kind of the resin 13.

In a case where the resin 13 is, for example, polyimide, for example, (i) a toluene solution containing a polyamide acid is prepared, as a polyamide acid solution, in the mixture preparing step by dissolving a polyamide acid, which is a polyimide precursor, in an organic solvent, (ii) the inorganic particles 3, such as Fe₃O₄ particles, which are dispersed in the organic solvent are added to the toluene solution, and (iii) a resultant solution is mixed by stirring. A mixed solution (dispersion liquid), in which the inorganic particles 3 are evenly dispersed, is thus prepared as the mixture 20.

In the processing step, (i) the mixed solution (dispersion liquid) is thinly poured into a reactor, which serves as a shaping die for shaping the mask substrate, and then (ii) cyclodehydration (imidization) reaction is undergone so that a conversion of the polyamide acid into polyimide is made. The mask substrate 11 having a thin plate shape is thus formed. In so doing, depending on the shaping die, (i) a mask substrate 11 in which the openings 12 are already formed can be formed or alternatively, (ii) a thin plate mask substrate 11 (thin plate member) in which the openings 12 have not been formed yet (see (b) of FIG. 1) can be shaped and then the openings 12 are formed in the thin plate mask substrate 11 (see (c) of FIG. 1). That is, in the processing step, the openings 12 can be formed in the shaping step by simultaneously carrying out the shaping step and the opening forming step. Alternatively, the opening forming step can be carried out independently of the shaping step.

As has been discussed, the imidization reaction can be undergone by use of (i) the thermal imidization method, (ii) the chemical imidization method using a catalyst, or (iii) a combination of the above methods (i) and (ii). In a case of the thermal imidization method, polymerization is carried out at a temperature of not lower than 200° C. In a case of the chemical imidization method, polymerization is carried out with use of an imidization catalyst.

In a case where (i) the resin 13 is a photo-curable resin and (ii) a photo-curable resin precursor is employed as the resin material 21, it is possible to adjust a thickness of the vapor deposition mask 1 by adjusting irradiation time of light. In such a case, the resin material 21 can contain a photo-polymerization initiator.

In the opening forming step, it is possible to form the openings 12 in the thin plate mask substrate 11 (thin plate member), in which the openings 12 have not been formed yet, by use of, for example, laser processing. Examples of a laser used in the laser processing include an excimer laser.

The mask substrate 11 formed in the shaping step can be (i) a single mask substrate 11 which is used as the vapor deposition mask 1 or (ii) a base substrate which is to be divided into pieces so that each of the pieces is used as a vapor deposition mask 1.

In a case where the mask substrate 11 formed in the shaping step is a base substrate, the processing step can further include a substrate dividing step of dividing the base substrate. In a case where the opening forming step is carried out after the shaping step, the substrate dividing step can be carried out before the opening forming step. However, in view of improving working efficiency, it is preferable to carry out the substrate dividing step after the opening forming step. In such a case, it is possible to form vapor deposition masks 1 by dividing the base substrate in the substrate dividing step.

The mask substrate 11 (i) is used, as it is, a vapor deposition mask 1 or (ii) is used while being fixed to a support such as a mask frame 14 (see (a) and (b) of FIG. 2).

Each of (a) and (b) of FIG. 2 is a view illustrating a production process of the vapor deposition mask 1 which includes the mask frame 14.

As illustrated in (a) and (b) of FIG. 2, the mask substrate 11 can be used as the vapor deposition mask 1, in a case where the mask substrate 11 is fixed to the mask frame 14.

When viewed from above, the mask frame 14 has an outer shape which is rectangle and which is identical to or one size larger than the mask substrate 11.

The mask frame 14 is not limited to have specific thickness and width when viewed from above. The mask frame 14, however, preferably has a high stiffness and a wide width so as to be prevented from being pulled and deformed by the mask substrate 11. As such, when viewed from above, the mask frame 14 preferably has a thickness of and a width of approximately 1 cm to 5 cm.

The mask frame 14 is not limited to be made of a particular material. The mask frame 14 is, however, preferably made of a magnetic substance in a case where the inorganic particles 3 are each a magnetic particle. The mask substrate 11 and the mask frame 14 are preferably made of identical materials, from the perspective that the occurrence of a thermal stress is restrained during the vapor deposition so that the vapor deposition mask 1 is prevented from deforming.

The mask substrate 11 can be fixed to the mask frame 14 by, for example, (i) overlapping the mask frame 14 and the mask substrate 11 and (ii) bonding the mask substrate 11 and the mask frame 14 together while applying tensile force.

A method of bonding the mask substrate 11 and the mask frame 14 is not particularly limited. For example, a circumferential part of the mask substrate 11 can be integrally bonded with use of an adhesive or an adhesion tape. A method of fixing the mask substrate 11 to the mask frame 14 is not limited as such, but various conventional publicly-known methods can be alternatively employed. The mask substrate 11 can alternatively be fixed to the mask frame 14 so that the mask substrate 11 are wound around the mask frame 14.

<Vapor Deposition Device 100>

FIG. 3 is a view illustrating an example schematic configuration of a vapor deposition device 100 which includes a vapor deposition mask 1 in accordance with Embodiment 1.

Note that the following description will discuss an example in which (i) an inorganic filler is inorganic particles 3 containing magnetic particles and (ii) magnetic force holds the vapor deposition mask 1. However, the vapor deposition device 100 in accordance with Embodiment 1 is not limited as such. Alternatively, the vapor deposition device 100 can be (i) a vapor deposition device which includes a vapor deposition mask 1 in which an inorganic filler having no magnetic property is used or (ii) a vapor deposition device which makes a scanning vapor deposition while the vapor deposition mask 1 is separated from a film formation target substrate 200.

In a case where an inorganic filler having no magnetic property is employed, the vapor deposition mask 1 and the film formation target substrate 200 can be fixed while they are in mechanical contact with each other. By depositing vapor deposition particles on the film formation target substrate 200 via the openings 12 of the vapor deposition mask 1 while the vapor deposition mask 1 and the film formation target substrate 200 are in contact with each other, it is possible to further restrain the occurrence of a vapor deposition shadow. This allows a formation of a higher-definition vapor-deposited film pattern.

Note that in a case where the vapor deposition mask 1 is not held by magnetic force, the vapor deposition device 100 does not necessarily include a magnetic force generating source 101.

As illustrated in FIG. 3, the vapor deposition device 100 in accordance with Embodiment 1 includes the vapor deposition mask 1, the magnetic force generating source 101, a vapor deposition source 102, a vapor deposition source moving device (not illustrated), a substrate moving device (not illustrated), and a substrate holder (not illustrated).

The substrate holder is a member for holding the vapor deposition mask 1, the magnetic force generating source 101, and the film formation target substrate 200. The vapor deposition mask 1 is held by the substrate holder together with the magnetic force generating source 101 and the film formation target substrate 200 while being brought into contact with the film formation target substrate 200 by the magnetic force generating source 101.

The magnetic force generating source 101 is provided on an opposite side to a side of the film formation target substrate 200 on which side the vapor deposition mask 1 is provided. That is, the magnetic force generating source 101 is provided on a side where the substrate holder for holding the film formation target substrate 200 is provided. The magnetic force generated by the magnetic force generating source 101 causes the vapor deposition mask 1 to attract the inorganic particles 3 mixed in the resin layer 2 of the vapor deposition mask 1 so that the vapor deposition mask 1 is in (close) contact with the film formation target substrate 200. Examples of the magnetic force generating source 101 include a magnet (e.g., magnet plate) and an electric magnet.

The vapor deposition source 102 is provided so as to (i) be opposite to the film formation target substrate 200 and (ii) face the vapor deposition mask 1. The vapor deposition source 102 is, for example, a container which houses therein a vapor deposition material 103. Note that the vapor deposition source 102 can be a container which directly houses therein the vapor deposition material 103. Alternatively, the vapor deposition source 102 can be configured to have a load lock pipe via which the vapor deposition material 103 is externally supplied to the container.

The vapor deposition source 102 has, for example, a rectangular shape. The vapor deposition source 102 has, on its upper surface (i.e., at a surface which faces the vapor deposition mask 1) side, a plurality of emission holes 102a (thorough holes, nozzles) via which the vapor deposition material 103 is emitted as the vapor deposition particles. The plurality of emission holes 102a are provided at equal pitches in, for example, a one-dimensional manner (i.e., a linear manner) or a two-dimensional manner (i.e., a tiled manner). Note that FIG. 3 illustrates an example in which the vapor deposition source 102 has the plurality of emission holes 102a. The vapor deposition source 102 can, however, have at least one emission hole 102a.

The vapor deposition source 102 generates gaseous vapor deposition particles, by heating the vapor deposition material 103 so that the vapor deposition material 103 is evaporated (in a case where the vapor deposition material 103 is a liquid material) or sublimated (in a case where the vapor deposition material 103 is a solid material). The vapor deposition source 102 emits, as the vapor deposition particles, the vapor deposition material 103 thus gasified toward the vapor deposition mask 1 via the plurality of emission holes 102a.

<Method of Vapor Deposition>

The following description will discuss, as an example of a method of vapor deposition in accordance with Embodiment 1, a method of vapor deposition using a vapor deposition device 100 illustrated in FIG. 3.

First, a film formation target substrate 200 and a vapor deposition mask 1 discussed above are caused to face each other. In so doing, a magnetic force generating source 101 is provided on a back surface side of the film formation target substrate 200 (see FIG. 3). This causes the magnetic force to attract the vapor deposition mask 1 so that the film formation target substrate 200 and the vapor deposition mask 1 are brought into contact with each other. Specifically, the magnetic force generated by the magnetic force generating source 101 attracts the inorganic particles 3, which are made up of magnetic particles and which are mixed in a resin layer 2, toward the magnetic force generating source 101. This causes the film formation target substrate 200 and the vapor deposition mask 1 to be in close contact with each other.

While the film formation target substrate 200 and the vapor deposition mask 1 are in (close) contact with each other, a vapor deposition is made while scanning at least one of (i) the film formation target substrate 200 with which the vapor deposition mask 1 is in contact (and fixed) and (ii) the vapor deposition source 102.

A vapor deposition material 103 (vapor deposition particles) which has been emitted via the emission holes 102a of the vapor deposition source 102 is deposited (vapor-deposited) on a surface of the film formation target substrate 200 via the openings 12 of the vapor deposition mask 1. The vapor deposition film 210, having a shape identical to that of the openings 12, is thus formed on the surface of the film formation target substrate 200.

According to Embodiment 1, (i) the inorganic particles 3, which are made up of magnetic particles are mixed in the resin layer 2 and (ii) the inorganic particles 3 are bonded to each other via the resin 13. This (i) prevents a problem of deflecting and/or peeling of a resin layer, which occurs to a conventional vapor deposition mask, (ii) prevents the vapor deposition mask 1 from floating around the openings 12, and (iii) secures close contact between the film formation target substrate 200 and the vapor deposition mask 1. Furthermore, since a resin is employed as a base material of the mask substrate 11, it is possible to obtain a pattern of openings with high accuracy. This allows an improvement in accuracy of a vapor deposition pattern.

The method of vapor deposition in accordance with Embodiment 1 can therefore be employed as a method of producing an EL display device such as an organic EL display device or an inorganic EL display device, by forming, for example, a light emitting layer, as a vapor deposition film 210, on the film formation target substrate 200.

The vapor deposition device 100 in accordance with Embodiment 1 can be also employed as a production device for producing an EL display device such as an organic EL display device or an inorganic EL display device.

With the configuration of the vapor deposition device 100, it is sufficient, like a conventional deposition device of magnet-type, that the magnetic force generating source 101, such as a magnet or an electric magnet, is provided on a side on which the substrate holder for holding the film formation target substrate 200 is provided. This eliminates the need for introducing a new mechanism, and therefore allows a reduction in production cost, and ultimately allows an improvement in productivity.

<Effect>

As has been discussed, Embodiment 1 employs a resin as a material of the mask substrate 11 so that it is possible (i) to easily form, with high accuracy, openings by use of laser processing or the like and (ii) to prevent the mask substrate 11 from stretching or deflecting due to heat generated under a high temperature condition necessitated during vapor deposition. The mask substrate 11 which is partially made of the resin 13 makes it possible to (i) reduce weight of the vapor deposition mask 1 and (ii) prevent the vapor deposition mask 1 from deflecting due to its own weight. Embodiment 1 therefore makes it possible to form a vapor-deposited film pattern with high definition.

It is possible to prepare, in accordance with a kind of an inorganic material used, a vapor deposition mask 1 having properties of the inorganic material (inorganic particles 3) by mixing, for example, the inorganic particles 3 as an inorganic material (inorganic filler) in the resin layer 2.

For example, in a case where the inorganic particles 3 are respective metal particles as has been discussed, it is possible for the vapor deposition mask 1 to enhance its strength. In a case where the inorganic particles 3 are respective magnetic particles, it is further possible to hold the vapor deposition mask 1 by magnetic force.

According to Embodiment 1, the resin material 21 and the inorganic particles 3 are processed into a mask, after they were mixed with each other. That is, in Embodiment 1, the resin material 21 and the inorganic particles 3 hardly separate from each other, because the resin material 21 and the inorganic particles 3 are processed into a mask in a state they have been mixed with each other.

According to the vapor deposition mask 1 in accordance with Embodiment 1, as has been discussed, the inorganic particles 3 are mixed in the resin layer 2. As such, unlike a conventional complex vapor deposition mask, the vapor deposition mask 1 does not employ a configuration in which a resin layer and a layer which is made of an inorganic substance are laminated as respective separated layers.

According to the vapor deposition mask 1 in accordance with Embodiment 1, materials are already mixed with each other and the inorganic particles 3 are bonded to each other by the resin 13. As such, unlike a conventional vapor deposition mask, peeling of a layer will not occur. This does not cause the inorganic particles 3 to separate from the resin 13, and ultimately does not cause the inorganic particles 3 to peel and fall from the resin layer 2.

According to Embodiment 1, the materials are first mixed with each other, and are then processed into a mask. This makes it possible to freely adjust a proportion of the inorganic particles 3 in the resin layer 2, and consequently makes it possible to freely adjust properties (e.g., hardness, sturdiness, and magnetic strength) of a resultant vapor deposition mask 1.

According to the vapor deposition mask 1 of Embodiment 1, the materials are mixed with each other. It is therefore possible to form the vapor deposition mask 1 in which an organic substance and an inorganic substance are more evenly mixed, as compared with a conventional vapor deposition mask.

The materials are mixed with each other in the vapor deposition mask 1 in accordance with Embodiment 1. It is therefore possible to prevent the vapor deposition mask 1 from warping due to a difference in thermal expansion coefficient between the resin layer and the metal layer, as compared with a case where a metal layer is laminated on a resin layer.

In a case where (i) the metal layer is laminated on the resin layer as with the conventional case and (ii) a metal layer (magnetic layer) having a certain thickness is further provided on a surface of the resin layer particularly for the purpose of enhancing attraction force caused by the magnetic force, vapor deposition particles that try to enter the resin layer at an incident angle smaller than a given angle are blocked by the metal layer formed on the resin layer. By thus further providing the metal layer (magnetic layer) on the metallic layer, an angle at which the vapor deposition particles can enter the openings 12 becomes smaller. This causes a reduction in utilization efficiency of the vapor deposition particles.

In contrast, according to Embodiment 1, the vapor deposition mask 1 includes no metal layer separately from the resin layer. This makes it possible to increase an angle at which the vapor deposition particles can enter, as compared with a conventional vapor deposition mask in which the metal layer is further provided on the resin layer. In a case where the vapor deposition is made with the use of the vapor deposition mask 1, it is possible to improve utilization efficiency of the vapor deposition particles. It is consequently possible to improve an efficiency in mass production.

According to Embodiment 1, materials are mixed with each other as has been discussed. It is therefore possible to reduce the number of production steps, as compared with the conventional case where one of the resin layer and the metal layer is formed and then the other is formed. This makes it possible to restrain an increase in percent defective due to integration of percent defectives in respective production steps. This ultimately makes it possible to inexpensively and efficiently produce the vapor deposition masks 1.

<Variation>

Embodiment 1 has discussed an example in which the inorganic particles 3 are employed as the inorganic filler. Embodiment 1 is, however, not limited as such. The inorganic filler can have the form as discussed in Embodiment 1 or can alternatively have a fibrous form (short fibers, spicula). Examples of such a fibrous inorganic filler include metal fibers. Note that, of course, the metal fibers can be metal fibers each made of a magnetic metal or metal fibers each made of a non-magnetic metal.

In terms of dispersibility, the inorganic filler is preferably the inorganic particles 3. The inorganic particles 3 are not limited to have a spherical form, and can have, for example, an elliptic form or an amorphous form.

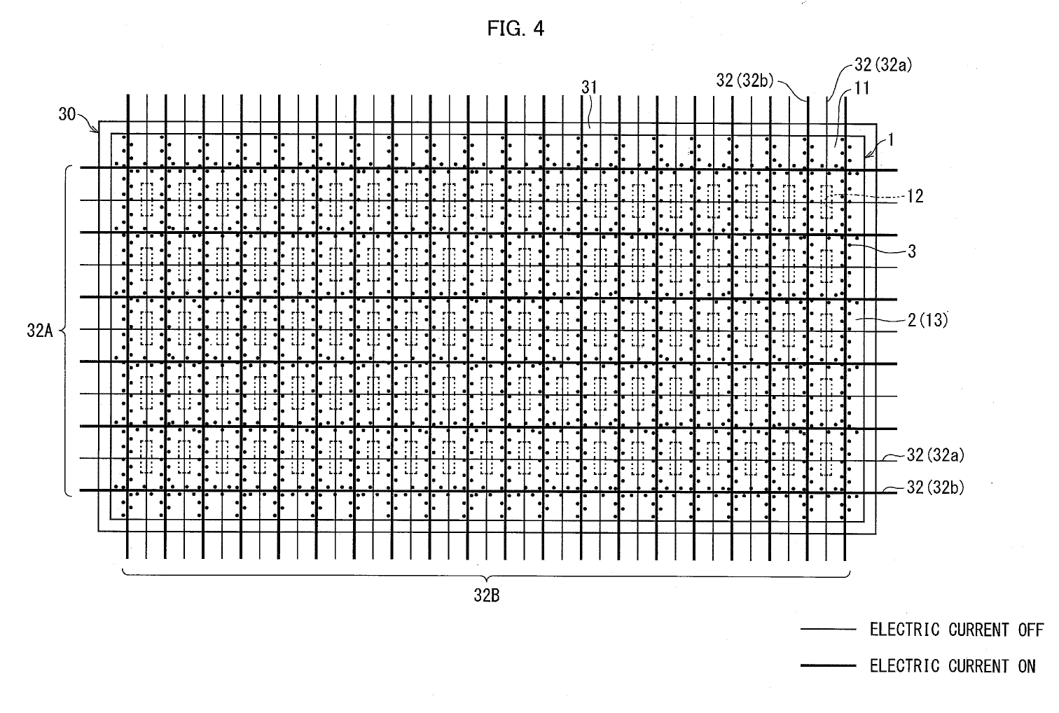

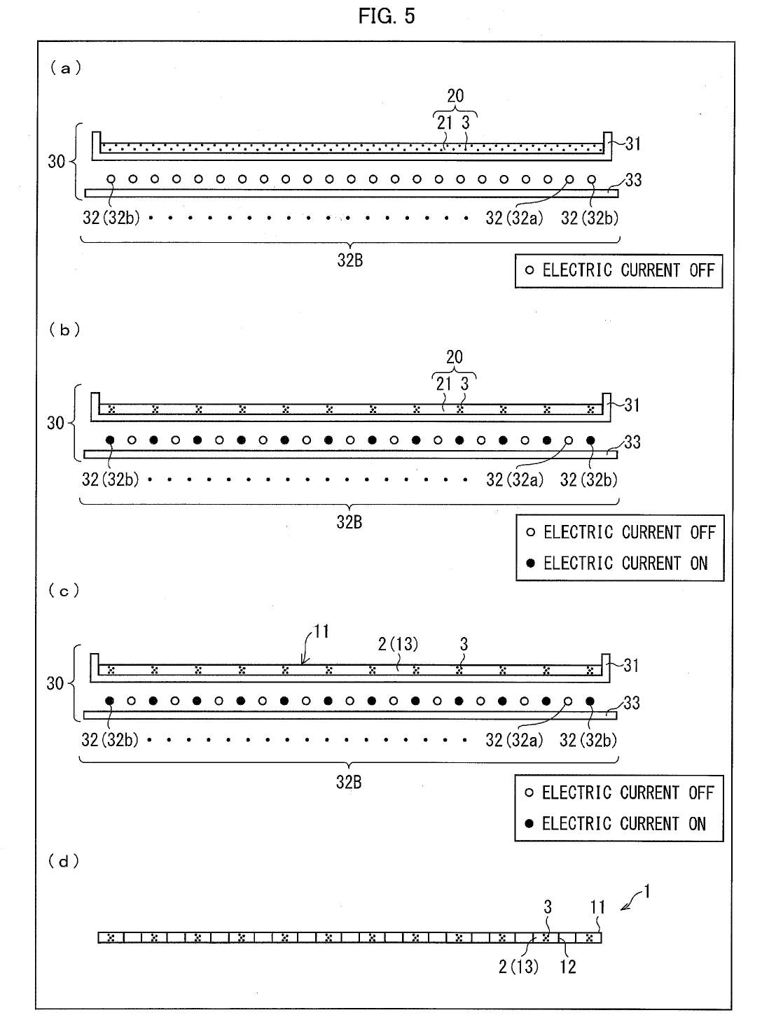

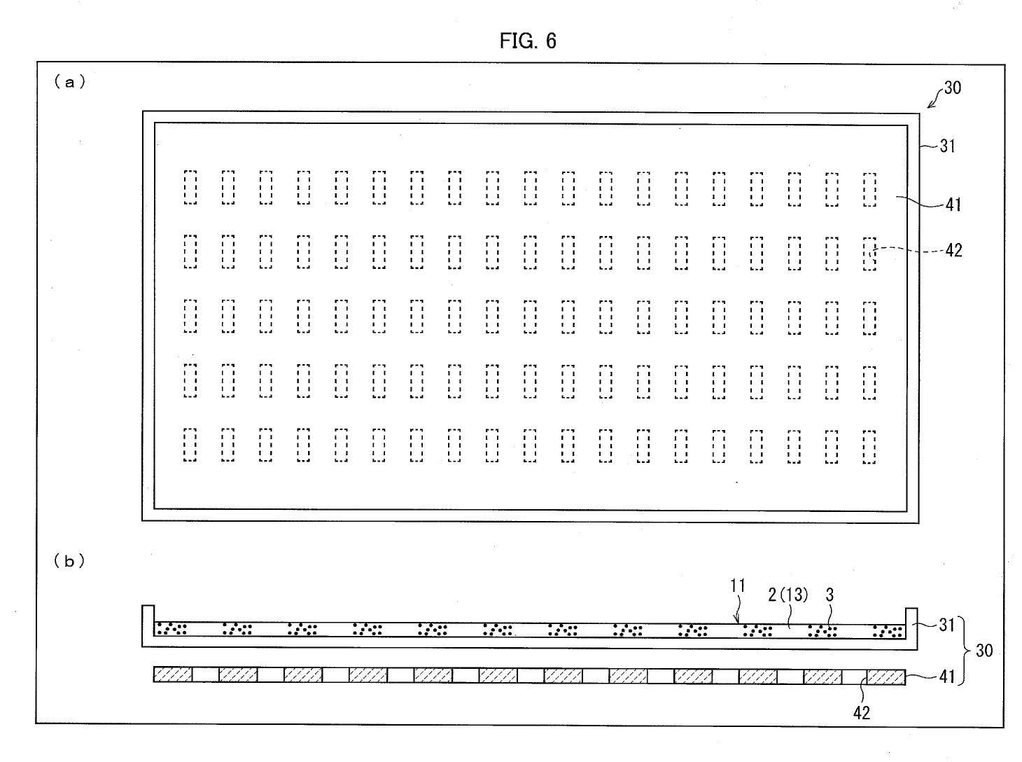

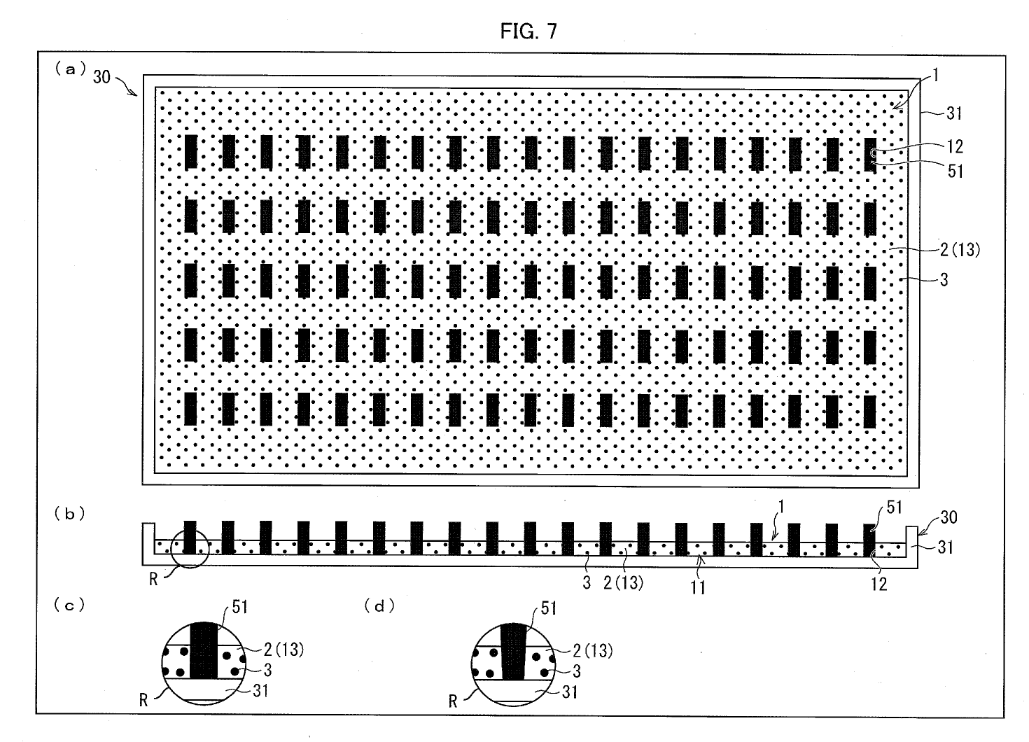

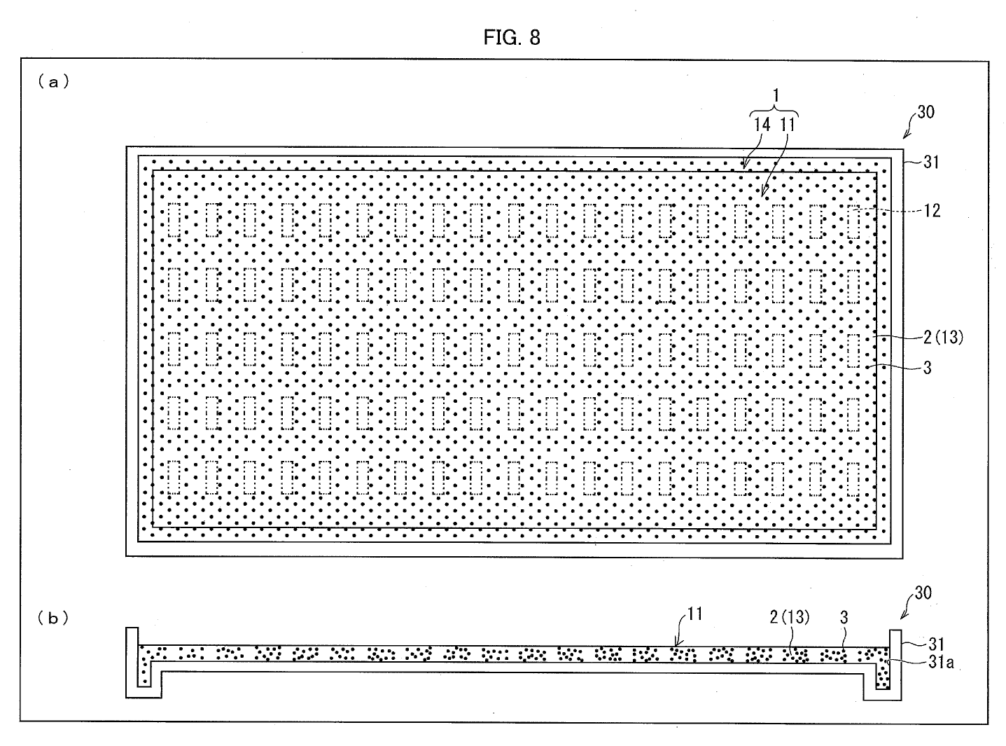

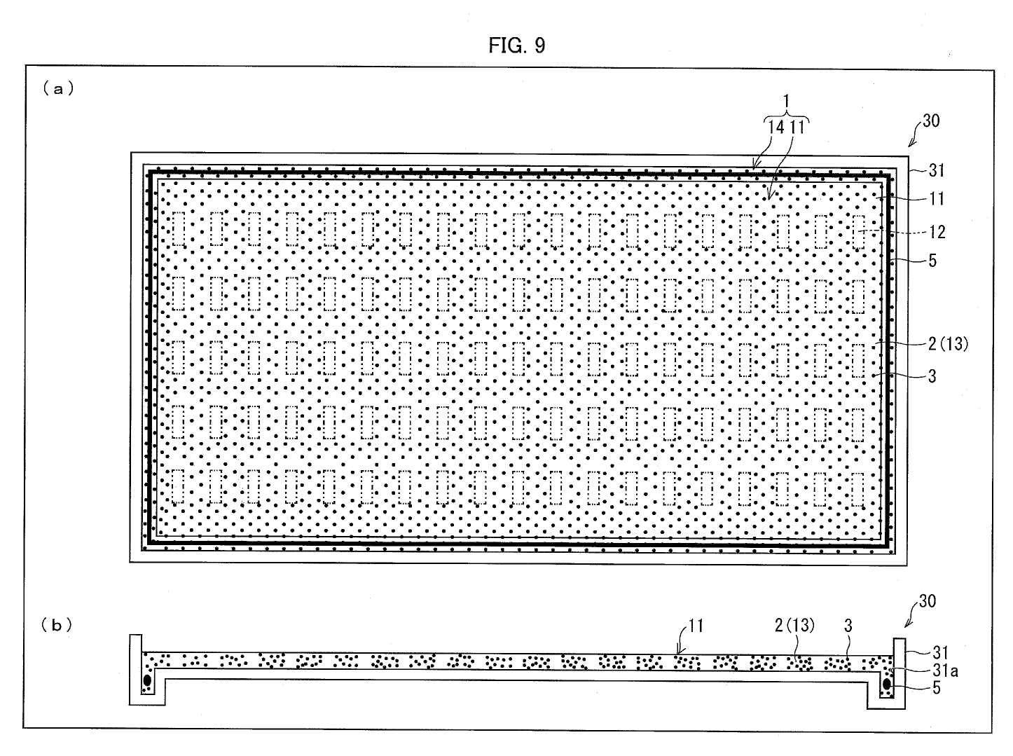

The following description will discuss Embodiment 2 of the present invention with reference to FIG. 4 and (a) through (d) of FIG. 5. Note that Embodiment 2 will discuss differences from Embodiment 1. The same reference numerals are given to members having functions identical to those of members discussed in Embodiment 1, and descriptions of such members are therefore omitted. It is of course possible to alter Embodiment 2 in a manner similar to Embodiment 1.

Embodiment 2 employs, as an inorganic filler, a magnetic filler which is made of a magnetic substance. Embodiment 2 will discuss an example in which inorganic particles 3 made up of magnetic particles are employed as an inorganic filler (i.e., magnetic filler). However, Embodiment 2 is not limited as such.

<Vapor Deposition Mask 1 and Vapor Deposition Device 100>

FIG. 4 is a plan view illustrating a schematic configuration of a main part of a mask production device 30, together with a mask substrate 11, in accordance with Embodiment 2. Note that in FIG. 4, a chain double-dashed line indicates openings 12, in a finally obtained vapor deposition mask 1, which are formed with respect to the mask substrate 11, in order to indicate a positional relationship between the openings 12 of the vapor deposition mask 1 and coils 32.

As illustrated in FIG. 4, the vapor deposition mask 1 and a vapor deposition device 100 in accordance with Embodiment 2 are identical to those of Embodiment 1, except that the vapor deposition mask 1 in accordance with Embodiment 2 has a configuration in which the inorganic particles 3 are, in a resin layer 2, unevenly distributed and dispersed (mixed) so as to surround the openings 12.

Note that FIG. 4 illustrates an example in which, as with Embodiment 1, the vapor deposition mask 1 has rectangular openings 12 which are arranged in a matrix manner.

According to the vapor deposition mask 1 illustrated in FIG. 4, in the resin layer 2, inorganic particles 3 are provided and unevenly distributed, when viewed from above, in a lattice manner (in a reticulated manner) so as to surround corresponding ones of the openings 12.

<Mask Production Device>

The following description will discuss, with reference to FIG. 4 and (a) through (c) of FIG. 5 out of (a) through (d) of FIG. 5, the mask production device 30 (vapor deposition mask production device) for use in production of the vapor deposition mask 1 in accordance with Embodiment 2.

(a) through (d) of FIG. 5 are cross-sectional views illustrating main parts of sequential steps of producing the vapor deposition mask 1 in accordance with Embodiment 2.

As illustrated in FIG. 4 and (a) through (c) of FIG. 5, the mask production device 30 in accordance with Embodiment 2 includes a reactor 31, which serves as a shaping die for shaping a mask substrate, a plurality of coils 32, a power source (not illustrated), a driving circuit (not illustrated), and a control circuit (not illustrated).

The reactor 31 is a processing container for housing, processing, and shaping a mixture 20, of which the mask substrate 11 is made, into a thin plate so that the mask substrate 11 is formed. Note that the reactor 31 preferably includes a heating mechanism (not illustrated) so as to heat the mixture 20 in the reactor 31.

A material of which the reactor 31 is made is not particularly limited. However, the reactor 31 is preferably made of a material which has no magnetic property or has low magnetic permeability. This makes it easier to control, while a magnetic field is generated inside the reactor 31, a condition of such a magnetic field.

Each of the plurality of coils 32 acts as a magnetic field generating source which generates a magnetic field in the reactor 31. As illustrated in FIG. 4, the plurality of coils 32 include (i) coil columns 32A each of which is made up of a group of coils 32 provided so as to extend in a row direction and (ii) coil columns 32B each of which is made up of a group of coils 32 provided so as to extend in a column direction. The coil columns 32A and the coil columns 32B are arranged in a lattice manner so that they intersect with each other when viewed from above.

Note that an insulating member (not illustrated), such as an insulating layer or an insulating sheet, is provided between the coil columns 32A and the coil columns 32B.

The plurality of coils 32 can be provided outside of the reactor 31, by causing the plurality of coils 32 to be held by a coil holding member 33 so as to face the reactor 31 (see (a) through (c) of FIG. 5. Alternatively, the plurality of coils 32 can be sealed in the reactor 31 or can be provided on a rear surface of the reactor 31. That is, the reactor 31 can double as a coil holding member. The coil holding member 33 can be (i) provided so as to be attachable to and detachable from the reactor 31 or (ii) provided independently of the reactor 31.

(a) through (c) of FIG. 5 each illustrate an example in which the plurality of coils 32 are provided so as to be located on a rear surface side of the reactor 31. However, Embodiment 2 is not limited as such. Alternatively, the coil holding member 33 can be provided above the reactor 31 after the mixture 20 is in the reactor 31.

An AC power source (not illustrated) is connected between ends of each of the plurality of coils 32. Note that a strength of the magnetic field can be controlled by adjusting an electric current which flows into the plurality of coils 32.

The control circuit supplies, to the driving circuit, a control signal for controlling the AC power source to (i) supply an electric current to each of the plurality of coils 32 (ON) or (ii) halt supplying of the electric current (OFF).

The driving circuit controls each of the plurality of coils 32 in accordance with the control signal supplied from the control circuit. That is, the driving circuit is controlled, by the control signal supplied from the control circuit, to turn on or turn off the electric current to be supplied to each of the plurality of coils 32. Of course, alternatively, the supply of the electric current to each of the plurality of coils 32 can be manually controlled.

<Method of Producing Vapor Deposition Mask 1>

According to Embodiment 2, the mixture 20 housed in the reactor 31 is shaped while a magnetic field, generated by the plurality of coils 32, is applied to the mixture 20. This causes the inorganic particles 3 contained in the mixture 20 to be unevenly distributed.

In a case where a magnetic field, generated by the plurality of coils 32, is applied to the mixture 20 in the reactor 31, the inorganic particles 3 contained in the mixture 20 is moved and oriented along lines of the magnetic force generated by the plurality of coils 32.

In a case where an electric current is applied to each of the plurality of coils 32, magnetic fields which are parallel to respective axes of the coils (i.e., directions in which the respective plurality of coils 32 extend) are formed. This allows the inorganic particles 3 to be oriented along the axes of the respective plurality of coils 32.

The following description will more specifically discuss, with reference to FIG. 4 and (a) through (d) of FIG. 5, a method of producing the vapor deposition mask 1 in accordance with Embodiment 2. Note that the following description will discuss a processing step with reference to an example in which a resin solution containing a resin precursor, such as polyamide acid, is employed as a resin material 21.

First, a mixed solution (dispersion liquid) which contains (i) the resin material 21 such as a resin solution containing, for example, a resin precursor and (ii) the inorganic particles 3 is poured, as the mixture 20, into the reactor 31 (see (a) of FIG. 5). Note that (a) of FIG. 5 illustrates a state where no electric current is supplied to each of the plurality of coils 32.

Subsequently, out of the plurality of coils 32, (i) coils 32a which are located, when viewed from above, above formation regions (opening formation regions) (regions in which the respective openings 12 are to be formed) of the respective openings 12 are turned off and (ii) coils 32b which are located, when viewed from above, so as to surround corresponding formation regions of the openings 12 and which do not overlap with the corresponding formation regions of the openings 12, are turned on (see FIG. 4 and (b) of FIG. 5). This causes the inorganic particles 3, contained in the mixture 20, to be oriented along the coils 32b to each of which an electric current is supplied.

This causes the inorganic particles 3, contained in the mixture 20, to be unevenly dispersed in regions other than the formation regions of the respective openings 12 so that the inorganic particles 3 surround corresponding formation regions of the openings 12.

Subsequently, the reactor 31 is, for example, heated while the inorganic particles 3 are unevenly distributed as illustrated in (c) of FIG. 5. This facilitates curing reaction of the resin material 21 contained in the mixture 20 in the reactor 31 (i.e., curing reaction of the resin precursor such as imidization of polyamide acid). This consequently causes a thin plate mask substrate 11 (thin plate member) to be formed in which substrate 11 the inorganic particles 3 are unevenly distributed in regions other than the formation regions of the respective openings 12 and on which substrate 11 the openings 12 have not been formed yet.

The mask substrate 11 is then removed from the reactor 31, and as illustrated in (d) of FIG. 5, the openings 12 are formed, by laser irradiation or the like, in corresponding formation regions (a region surrounded by the inorganic particles 3) in the mask substrate 11. This makes it possible to prepare a mask substrate 11 in which the inorganic particles 3 are unevenly distributed so that (i) the inorganic particles 3 surround corresponding ones of the openings 12 and (ii) the inorganic particles 3 are provided between adjacent ones of the openings 12 so as to be parallel to corresponding ones of the openings 12.

<Effect>

According to Embodiment 2, the orientation of the magnetic field generated by a magnetic substance is thus utilized so that the inorganic particles 3 made of magnetic particles are oriented, by causing the magnetic field generating source, such as the plurality of coils 32, to generate the magnetic field in a direction in which the inorganic particles 3 are oriented. This causes the inorganic particles 3, which are contained in the mixture 20, to be unevenly distributed.

In a case where openings 12 are formed by using a laser, the openings 12 are formed by heat which is generated by laser irradiation. As such, in a case where (i) the mask substrate 11 contains an inorganic filler made of a material having high heat conductivity and (ii) the inorganic filler is located in a region in which an opening 12 is to be formed in the opening forming step, heat generated by the laser is conducted toward the inorganic filler. This may cause a problem that the opening 12 is likely not to be formed in its intended shape and size.

Some people consider that an amount of the inorganic particles 3 may be reduced so as to address such a problem. Though depending on a material of the inorganic particles 3, in a case where the vapor deposition mask 1 is held by magnetic force and the inorganic particles 3 are, for example, Fe₃O₄ particles, it is necessary to prepare not less than 20 wt % of the inorganic particles 3 with respect to an entire weight of the vapor deposition mask 1.

In view of the circumstances, in a case where the inorganic particles 3 are magnetic particles, it is preferable that (i) a certain content of the inorganic particles 3 is secured and (ii) the inorganic particles 3 are less contained (ideally, not contained), than in the other regions, in the formation regions of the openings 12 of the mask substrate 11 (i.e., regions, of the mask substrate 11, in which no opening 12 has been formed yet but openings 12 are to be formed).

It is consequently possible to realize, in the mask substrate 11, (a) a first region where the inorganic particles 3 are more contained and (b) a second region where the inorganic particles 3 are less contained, by shaping the mask substrate 11 in a state where (i) the magnetic field is applied to the first region and (ii) no magnetic field is applied to the second region (e.g., openings 12), in a case of shaping, for example, the mask substrate 11 as the vapor deposition mask 1.

The inorganic particles 3 are unevenly distributed in a region, other than the formation regions of the respective openings 12, in which the magnetic field is generated. Whereas, the inorganic particles 3 are hardly distributed in the formation regions, of the respective openings 12, in which no magnetic field is generated. That is, a filling density of the inorganic particles 3 is extremely higher in the regions other than the opening formation regions, than in the opening formation regions. Note that the inorganic particles 3 are evenly dispersed in a thickness direction, in a region where the magnetic field is generated.

According to Embodiment 2, the inorganic particles 3 are thus concentrated by the magnetic force in a region other than the formation regions of the respective openings 12. This makes it easier to carry out laser processing with respect to openings 12, and makes it possible to form the openings 12 with high accuracy. This also eliminates waste of the inorganic particles 3, and therefore allows a reduction in production cost.

According to Patent Literature 1, metal flakes made of a metal film are randomly formed, by plating, on a resin film. This causes a fluctuation in physical property from place to place.

According to, for example, Patent Literature 1, (i) the metal flakes are formed by using a magnetic metal material and (ii) a vapor deposition is made while a TFT substrate and the vapor deposition mask are brought into close contact with each other by a magnetic force chuck. The magnetic force chuck uses an electric magnet which is provided on an opposite side to a side of the TFT substrate, which is a film formation target substrate 200, on which side the vapor deposition mask is provided.

Since the metal flakes made of a metal film are, however, randomly formed, the vapor deposition mask disclosed in Patent Literature 1 has, around an opening (e.g., a region between adjacent openings), (i) a region in which the metal flakes are present and (ii) a region in which no metal flake is present. It is therefore likely that a region exists in which close contact between the TFT substrate and the vapor deposition mask is insufficient. This causes the vapor deposition mask to partially float, and consequently causes a reduction in accuracy of a vapor deposition pattern.

In contrast, according to Embodiment 2, the inorganic particles 3 made up of magnetic particles are oriented so as to surround the openings 12. This makes it possible to (i) prevent the vapor deposition mask 1 from floating around the openings 12 and (ii) secure close contact between the film formation target substrate 200 and the vapor deposition mask 1.

Embodiment 2 therefore makes it possible to make a vapor deposition while the film formation target substrate 200 and the vapor deposition mask 1 are in close contact with each other, particularly around the openings 12 as has been discussed. This allows an improvement in accuracy of a vapor deposition pattern.

Note that Embodiment 2 has discussed an example in which the openings 12 are arranged in a matrix manner. It is, however, also possible for the inorganic particles 3 to be unevenly distributed so as to surround the openings 12, regardless of the number, arrangement, and sizes of the openings 12, by (i) halting supplying of an electric current to the coils 32a, which are located, when viewed from above, in the formation regions (opening formation regions) of the respective openings 12 and (ii) supplying an electric current to coils 32b, which are located so as to surround corresponding formation regions of the openings 12 and which do not overlap, when viewed from above, with the formation regions of the openings 12. In a case where the openings 12 are, for example, provided only in a one-dimensional direction, it is possible to cause the inorganic particles 3 to be unevenly distributed so as to surround the openings 12, by supplying an electric current only to the coils 32b which surround the openings 12 arranged in the one-dimensional direction. By thus using the coils 32 as a magnetic field generating source, it is possible to provide a mask production device 30 which is applicable to production of various types of the vapor deposition mask 1.

Embodiment 2 has discussed an example in which the inorganic particles 3 made up of magnetic particles are employed as an inorganic filler. The same, however, applies to cases where a magnetic filler made of a magnetic substance is employed as an inorganic filler. That is, it is needless to say that Embodiment 2 is also applicable to cases where a magnetic filler made of a magnetic substance is employed as an inorganic filler.

The following description will discuss Embodiment 3 of the present invention with reference to (a) and (b) of FIG. 6. Note that Embodiment 3 will discuss a difference from Embodiments 1 and 2. The same reference numerals are given to members having functions identical to those of members discussed in Embodiments 1 and 2, and descriptions of such members are therefore omitted. It is of course possible to alter Embodiment 3 in a manner similar to Embodiments 1 and 2.

As with Embodiment 2, Embodiment 3 will discuss an example in which inorganic particles 3 made up of magnetic particles are employed as an inorganic filler. The Embodiment 3 is, however, not limited as such.

<Vapor Deposition Mask 1 and Vapor Deposition Device 100>

A vapor deposition mask 1 in accordance with Embodiment 3 has a configuration in which the inorganic particles 3 made up of a magnetic substance are evenly dispersed in a resin layer 2. Note that the vapor deposition mask 1 and a vapor deposition device 100 in accordance with Embodiment 3 are identical in configuration to those discussed in Embodiment 1 and their descriptions and illustration are therefore omitted.

<Mask Production Device 30>

(a) of FIG. 6 is a plan view illustrating a schematic configuration of a main part of a mask production device 30 in accordance with Embodiment 3. (b) of FIG. 6 is a cross-sectional view illustrating the schematic configuration of the main part of the mask production device 30 together with a mask substrate 11 which is in a mask substrate shaping step.

As illustrated in (a) and (b) of FIG. 6, the mask production device 30 in accordance with Embodiment 3 includes (i) a reactor 31 which serves as a shaping die for shaping a mask substrate and (ii) a magnetic mask 41 which is made of, for example, a magnet or an electric magnet and which serves as a magnetic field generating source.

The magnetic mask 41 is formed to be identical in shape to the mask substrate 11 to be prepared and has openings 42 which are identical in shape to respective openings 12 of the mask substrate 11.

As illustrated in (a) and (b) of FIG. 6, the magnetic mask 41 is provided, for example, below the reactor 31 (i.e., provided on a rear surface side of the reactor 31).

<Method of Producing Vapor Deposition Mask 1>

The following description will discuss a method of producing a vapor deposition mask 1 in accordance with Embodiment 3, by exemplifying a case in which a resin solution, containing a resin precursor such as polyamide acid, is employed as a resin material 21. Note that a processing step will be discussed below.

In a mask substrate shaping step in accordance with Embodiment 3, (i) the magnetic mask 41, which is identical in shape to a mask substrate 11 to be prepared, is provided below the reactor 31 and (ii) a magnetic field generated by the magnetic mask 41 is applied to a mixture 20 in the reactor 31.

According to Embodiment 3, the inorganic particles 3 contained in the mixture 20 moves along lines of the magnetic force generated by the magnetic mask 41. This causes the inorganic particles 3, contained in the mixture 20, to be unevenly distributed in accordance with the shape of the magnetic mask 41 when viewed from above.

That is, with the configuration of Embodiment 3, the inorganic particles 3 contained in the mixture 20 are unevenly dispersed, by the magnetic field generated by the magnetic mask 41, in a region that overlap with a region, of the magnetic mask 41, other than the openings 42 when viewed from above, i.e., in regions other than formation regions of the respective openings 12 of the mask substrate 11 when viewed from above. Note that the inorganic filler, made of a magnetic substance, is evenly dispersed in a thickness direction, in a region where the magnetic field is generated (i.e., in regions facing the respective openings 42 of the magnetic mask 41 when viewed from above).

In Embodiment 3, heat is applied to, for example, the reactor 31 while the inorganic particles 3 are thus unevenly distributed, as with Embodiment 2. This facilitates curing reaction of the resin material 21 contained in the mixture 20 in the reactor 31 (i.e., curing reaction of the resin precursor such as imidization of polyamide acid). This consequently causes a thin plate mask substrate 11 (thin plate member) to be formed in which substrate 11 the inorganic particles 3 are unevenly distributed in regions other than the formation regions of the respective openings 12 and on which substrate 11 the openings 12 have not been formed yet.

By, for example, laser irradiation, the openings 12 are formed in the formation regions (regions surrounded by the corresponding inorganic particles 3) of the respective openings 12 of the mask substrate 11. This makes it possible to prepare the mask substrate 11 including the resin layer 2 in which the inorganic particles 3 are evenly dispersed.

<Effect>

Embodiment 3 utilizes a magnetic field orientation of a magnetic substance so that a magnetic field is generated, by a magnetic field generating source, in a direction in which the inorganic particles 3 are forced to be oriented. This causes the inorganic particles 3 in the mixture 20, which are made up of magnetic particles, to be unevenly distributed.

In a case where (i) magnetic particles are employed as the inorganic particles 3 and (ii) the resin material 21 is merely mixed with the inorganic particles 3, the inorganic particles 3 are aggregated each other even in a case where a dispersant or the like is used. This causes a problem that (i) the inorganic particles 3 are unevenly mixed in the resin layer 2 or (ii) the inorganic particles 3 cannot be mixed with each other in the resin layer 2.

It is, however, possible to address such a problem as has been discussed. Specifically, it is consequently possible to realize, in the mask substrate 11, (a) a first region where the inorganic particles 3 are more contained and (b) a second region where the inorganic particles 3 are less contained, by shaping the mask substrate 11 in a state where (i) the magnetic field is applied to the first region and (ii) no magnetic field is applied to the second region (e.g., openings 12), in a case of shaping, for example, the mask substrate 11 as the vapor deposition mask 1.

The inorganic particles 3 are unevenly distributed, when viewed from above, in regions, other than the openings 42, of the magnetic mask 41 in which regions a magnetic field is generated, i.e., in regions, other than the formation regions of the respective openings 12, of the mask substrate 11. An inorganic particle 3 exists hardly at all in the formation regions, of the respective openings 12, in which a magnetic field is not generated. That is, a filling density of the inorganic particles 3 is extremely higher in the regions other than opening formation regions, than in the opening formation regions.

As described above, Embodiment 3 makes it possible to form, as a vapor deposition mask, an inorganic-particle-containing resin mask (magnetic-particle-containing resin mask, magnetic-filler-containing resin mask) in which the inorganic particles 3 are dispersed in a shape substantially identical to a shape of the magnetic mask 41.

According to Embodiment 3, the inorganic particles 3 are thus concentrated by the magnetic force in a region other than the formation regions of the respective openings 12, as with Embodiment 2. This makes it easier to carry out laser processing with respect to openings 12, and makes it possible to form the openings 12 with high accuracy. This eliminates waste of the inorganic particles 3, and therefore allows a reduction in production cost.

As with Embodiment 2, Embodiment 3 has discussed an example in which the inorganic particles 3 made up of magnetic particles are employed as an inorganic filler. The same, however, applies to cases where a magnetic filler made of a magnetic substance is employed as an inorganic filler. That is, it is needless to say that Embodiment 3 is also applicable to cases where a magnetic filler made of a magnetic substance is employed as an inorganic filler.

The following description will discuss Embodiment 4 of the present invention with reference to (a) through (d) of FIG. 7. Note that Embodiment 4 will discuss differences from Embodiments 1 through 3. The same reference numerals are given to members having functions identical to those of members discussed in Embodiments 1 through 3, and descriptions of such members are therefore omitted. It is of course possible to alter Embodiment 4 in a manner similar to Embodiments 1 through 3.

As with Embodiments 1 through 3, Embodiment 4 will discuss an example in which inorganic particles 3 are employed as an inorganic filler. Embodiment 4 is, however, not limited as such.

<Vapor Deposition Mask 1 and Vapor Deposition Device 100>

A vapor deposition mask 1 in accordance with Embodiment 4 has a configuration in which the inorganic particles 3 are evenly dispersed in a resin layer 2. Note that the vapor deposition mask 1 and a vapor deposition device 100 in accordance with Embodiment 4 are identical in configuration to those discussed in, for example, Embodiment 1, and their descriptions are therefore omitted.

<Mask Production Device 30>

(a) of FIG. 7 is a plan view illustrating a schematic configuration of a main part of a mask production device 30, together with a mask substrate 11 which is in a mask substrate shaping step, in accordance with Embodiment 4. (b) of FIG. 7 is a cross-sectional view illustrating the schematic configuration of the main part of each of the mask production device 30 and the mask substrate 11 illustrated in (a) of FIG. 7. Each of (c) and (d) of FIG. 7 is an enlarged view illustrating an example schematic configuration of the main part, in a region R illustrated in (b) of FIG. 7, of each of the mask production device 30 and the mask substrate 11.

As illustrated in (a) through (c) of FIG. 7, the mask production device 30 in accordance with Embodiment 4 is identical to a mask production device for producing the vapor deposition masks 1 in accordance with respective Embodiments 1 through 3, except that a reactor 31, which serves as a shaping die for shaping a mask substrate, of Embodiment 4 includes protrusions 51, configured to form openings 12 in the mask substrate 11, so that the protrusions 51 correspond to respective opening formation regions of the mask substrate 11.

Note that, in Embodiment 4, whether or not to apply a magnetic field to the reactor 31 is not particularly limited. The mask production device 30 can employ, as a magnetic field generating source, (i) a coil 32 or (ii) a magnetic mask which is identical in shape to the vapor deposition mask 1. This allows an effect, similar to that of Embodiment 2 or 3, to be brought about.

Preferably, the protrusions 51 are provided so as to be attachable to and detachable from the reactor 31. The protrusions 51 are preferably made of, for example, a removable material such as a dissolvable material. In a case where the protrusions 51 are made of, for example, a resist material, it is possible to remove the protrusions 51 with use of a resist-removing agent after shaping the mask substrate 11.

As illustrated, for example, in (c) and (d) of FIG. 7, it is possible to change a shape, such as a taper angle, of the openings 12 of the mask substrate 11, by changing a shape of wall surfaces of the respective protrusions 51 provided on the reactor 31.

As illustrated in (c) of FIG. 7, a protrusion 51 can have a square column shape which is, when viewed from above, identical to that of an opening 12 of the mask substrate 11. Alternatively, the protrusion 51 can have a reversed taper shape so that an angle between a wall surface of the protrusion 51 and a surface, of the reactor 31, on which the protrusion 51 is provided (i.e., inner wall of the reactor 31) is not greater than 90° (see (d) of FIG. 7).

(d) of FIG. 7 illustrates an example in which the protrusions 51 has a reversed taper shape. Alternatively, the protrusion 51 can have a normal taper shape so that the angle between the wall surface of the protrusion 51 and the surface, of the reactor 31, on which the protrusion 51 is provided is greater than 90°.

In a case where the protrusion 51 is provided to have a taper shape (reversed taper shape or normal taper shape), it is possible to form the opening 12 of the mask substrate 11 in a taper shape identical to that of the protrusion 51.

It is possible to more effectively restrain the occurrence of a vapor deposition shadow, by making a vapor deposition in a state where (i) a wall of the opening 12 of the mask substrate 11 is formed in a taper shape so as to have an inclination and (ii) the vapor deposition mask 1 and the film formation target substrate 200 are provided so that a diameter of the opening 12 of the mask substrate 11 becomes smaller toward the film formation target substrate 200.

<Method of Producing Vapor Deposition Mask 1>

The following description will discuss a method of producing the vapor deposition mask 1 in accordance with Embodiment 4. Note that Embodiment 4 is identical in mixture preparing step to Embodiment 1, and therefore a processing step will be discussed below.

Note that the following description will discuss an example in which the protrusions 51 have a removable structure. Embodiment 4 is, however, not limited as such. Alternatively, though depending on a composition of a mixture 20, a size of the openings 12, and the like, the mask substrate 11 can be removed from the reactor 31, on which the protrusions 51 are provided, by using a mold releasing agent or the like, instead of removing the protrusions 51 from the reactor 31.

In Embodiment 4, the reactor 31, on which the protrusions 51 are provided, is prepared so that the openings 12 are formed in the mask substrate 11. For example, removable protrusions 51 are provided on the reactor 31 (protrusion forming step). Subsequently, the mixture 20 (e.g., mixed solution) is poured into the reactor 31 as with Embodiments 1 through 3, and is shaped into a mask substrate 11 as with Embodiments 1 through 3. The openings 12 are then formed in the mask substrate 11 by taking out (removing) the protrusions 51.

<Effect>

According to Embodiment 4, since the protrusions 51 can be removed after shaping the mask substrate 11, it is possible to easily remove the mask substrate 11 from the reactor 31.

According to Embodiment 4, the protrusions 51 are provided, on the reactor 31, so as to correspond to the respective opening formation regions of the mask substrate 11. This causes the mixture 20 to be eliminated from the opening formation regions during shaping the mask substrate 11. With the configuration of Embodiment 4, it is therefore possible to shape the mask substrate 11 having the openings 12 by shaping the mask substrate 11 with use of the reactor 31, without separately carrying out laser irradiation or the like. It follows that, with the configuration of Embodiment 4, it is possible to, in a step of shaping the mask substrate 11, concurrently shape the mask substrate 11 and form the openings 12 in the mask substrate 11.

Embodiment 4 has discussed an example in which the inorganic particles 3 are employed as an inorganic filler. An inorganic filler, similar to those discussed in Embodiments 1 through 3, can be alternatively employed as such an inorganic filler.

The following description will discuss Embodiment 5 of the present invention with reference to (a) and (b) of FIG. 8. Note that Embodiment 5 will discuss differences from Embodiments 1 through 4. The same reference numerals are given to members having functions identical to those of members discussed in Embodiments 1 through 4, and descriptions of such members are therefore omitted. It is of course possible to alter Embodiment 5 in a manner similar to Embodiments 1 through 4.

As with Embodiments 1 through 4, Embodiment 5 will discuss an example in which inorganic particles 3 are employed as an inorganic filler. Embodiment 5 is, however, not limited as such.

<Vapor Deposition Mask 1 and Vapor Deposition Device 100>

(a) of FIG. 8 is a plan view illustrating a schematic configuration of a main part of a mask production device 30, together with a mask substrate which is in a mask substrate shaping step, in accordance with Embodiment 5. (b) of FIG. 8 is a cross-sectional view illustrating the schematic configuration of the main part of each of the mask production device 30 and a mask substrate 11 illustrated in (a) of FIG. 8.

Embodiment 1 has discussed an example in which the mask substrate 11 is fixed to a mask frame 14 after being shaped.

As illustrated in (a) and (b) of FIG. 8, a vapor deposition mask 1 and a vapor deposition device 100 in accordance with Embodiment 5 are identical to those discussed in Embodiment 1, except that (i) the mask substrate 11 and the mask frame 14 of the vapor deposition mask 1 of Embodiment 5 are monolithically shaped from an identical material and (ii) no bonding part is provided in Embodiment 5.

Note that, in a case where the mask substrate 11 and the mask frame 14 are monolithically shaped as discussed above, the mask substrate 11 preferably has a thickness of approximately 10 μm to 30 μm in order to restrain the occurrence of a vapor deposition shadow. A thickness of the mask frame 14 and a width of the mask frame 14 when viewed from above are not particularly limited. Such thickness and width are each typically set to be approximately 1 cm to 5 cm.

<Mask Production Device 30>

As illustrated in (a) and (b) of FIG. 8, the mask production device 30 in accordance with Embodiment 5 is identical to a mask production device for producing vapor deposition masks 1 in accordance with respective Embodiments 1 through 4, except that a reactor 31 of Embodiment 5, which serves as a shaping die for shaping a mask substrate, has a groove 31a for forming the mask frame 14 along a circumferential part of the mask substrate 11.

Note that, in Embodiment 5, whether or not to apply a magnetic field to the reactor 31 is not particularly limited. The mask production device 30 can employ, as a magnetic field generating source, (i) a coil 32 or (ii) a magnetic mask which is identical in shape to the vapor deposition mask 1. The reactor 31 can also be provided with protrusions 51 as with Embodiment 4 (through not illustrated). This allows an effect, similar to those brought about by Embodiments 2 through 4.

<Method of Producing Vapor Deposition Mask 1>

The following description will discuss a method of producing the vapor deposition mask 1 in accordance with Embodiment 5. Note that Embodiment 5 is identical in mixture preparing step to Embodiment 1, and therefore a processing step will be discussed below.

According to Embodiment 5, the reactor 31 is provided with the groove 31a for forming the mask frame 14. When, for example, a mixed solution (dispersion liquid), which serves as a mixture 20, is poured into the reactor 31 as with Embodiment 1 through 4, the mixed solution is also poured into the groove 31a of the reactor 31. This allows the mask substrate 11 and the mask frame 14 of the vapor deposition mask 1 to be concurrently shaped from a single material.

Note that in the processing step of Embodiment 5, (i) openings 12 can be formed in a shaping step by concurrently carry out the shaping step and an opening forming step or alternatively (ii) the opening forming step can be carried out separately from the shaping step.

<Effect>

With the configuration of Embodiment 5, it is possible to concurrently prepare a mask substrate 11 and a frame part which is employed as the mask frame 14.

According to Embodiment 5, it is unnecessary to separately carrying out bonding and/or fixing of the mask substrate 11 and the mask frame 14. This makes it possible to (i) reduce the number of the production steps and (ii) reduce the time required for producing the vapor deposition mask 1, as compared with a case where the mask substrate 11 and the mask frame 14 are bonded and/or fixed to each other after shaping the mask substrate 11.

Since the mask substrate 11 and the mask frame 14 are monolithically formed by use of a single material, it is also possible to restrain the occurrence of a thermal stress during vapor deposition. This prevents the vapor deposition mask 1 from deforming.

Embodiment 5 has discussed an example in which the inorganic particles 3 are employed as an inorganic filler. An inorganic filler, similar to those discussed in Embodiments 1 through 4 can be alternatively employed as such an inorganic filler.

The following description will discuss Embodiment 6 of the present invention with reference to (a) and (b) of FIG. 9. Note that Embodiment 6 will discuss differences from Embodiments 1 through 5. The same reference numerals are given to members having functions identical to those of members discussed in Embodiments 1 through 5, and descriptions of such members are therefore omitted. It is of course possible to alter Embodiment 6 in a manner similar to Embodiments 1 through 5.

As with Embodiments 1 through 5, Embodiment 6 will discuss an example in which inorganic particles 3 are employed as an inorganic filler. However, Embodiment 5 is not limited as such.

<Vapor Deposition Mask 1 and Vapor Deposition Device 100>

(a) of FIG. 9 is a plan view illustrating a schematic configuration of a main part of a mask production device 30, together with a mask substrate 11 which is in a mask substrate shaping step, in accordance with Embodiment 6. (b) of FIG. 9 is a cross-sectional view illustrating the schematic configuration of the main part of each of the mask production device 30 and the mask substrate 11 illustrated in (a) of FIG. 9.

As illustrated in (a) and (b) of FIG. 9, a vapor deposition mask 1 in accordance with Embodiment 6 is identical to Embodiment 5, except that a mask frame 14 includes therein a reinforcing member 5 configured to reinforce a strength of the mask frame 14.

A material of which the reinforcing member 5 is made is not particularly limited. In a case where the inorganic particles 3 are made of magnetic particles, it is preferable for the reinforcing member 5 to be made of a magnetic substance.

For example, a reinforcing member 5, made of a material identical to that of the inorganic particles 3, can be employed as the reinforcing member 5. Note that the reinforcing member 5 is not particularly limited in configuration, provided that it can reinforce the strength of the mask frame 14. The reinforcing member 5 can be made of, for example, a stainless steel SUS430. The stainless steel SUS430 has high stiffness, and is conventionally used as a typical material for a mask frame. The stainless steel SUS430 can be therefore suitably employed as the reinforcing member 5.

Note that a size of and a shape of the reinforcing member 5 are not particularly limited, provided that the reinforcing member 5 can be mixed in a groove 31a of a reactor 31. The reinforcing member 5 can be, for example, granulated so as to have a size larger than the inorganic particles 3, a pillar, a frame or the like. As has been discussed above, a thickness of the mask frame and a width of the mask frame 14 when viewed from above are not particularly limited. Such thickness and width are each typically set to be 1 cm to 5 cm. Particularly, a frame part of a conventional vapor deposition mask is often set to be 3 cm to 5 cm per side, and the mask frame 14 can be set in a manner similar to such a frame part. The reinforcing member 5 is preferably fittable in such a mask frame 14.

<Method of Producing Vapor Deposition Mask 1>

The following description will discuss a method of producing a vapor deposition mask 1 in accordance with Embodiment 6. Note that Embodiment 6 is identical in mixture preparing step to Embodiment 1, and therefore a processing step will be discussed below.

Furthermore, the mask production device 30 used in Embodiment 6 is identical to the mask production device 30 in accordance with Embodiment 5. Descriptions of the mask production device 30 are therefore omitted in Embodiment 6.

The vapor deposition mask 1 in accordance with Embodiment 6 can be produced by a method similar to Embodiment 5, except that, when, for example, a mixed solution (dispersion liquid) which serves as a mixture 20 is poured into the reactor 31 in a shaping step of Embodiment 5, (i) the reinforcing member 5 of Embodiment 6 is put in the groove 31a of the reactor 31 and then (ii) the mixed solution is poured into the reactor 31.

<Effect>

With the configuration of Embodiment 6, the reinforcing member 5 is put in the groove 31a of the reactor 31. This makes it possible to (i) reduce the time required for shaping the mask frame 14, (ii) enhance the strength of the mask frame 14, and (iii) prevent the vapor deposition mask 1 from deforming.

[Main Points]

A method of producing a vapor deposition mask in accordance with a first aspect of the present invention is a method of producing a vapor deposition mask 1 including a mask substrate 11 having openings 12, each of which causes vapor deposition particles (vapor deposition material 103) to pass therethrough, the method including the steps of: (a) preparing a mixture 20 which contains a resin material 21 and an inorganic filler (e.g., inorganic particles 3 or inorganic fibers); and (b) shaping, with use of a shaping die (reactor 31), the mixture 20 so that the mask substrate 11 is shaped, the mask substrate 11 containing (i) a resin 13 made of the resin material 21 and (ii) the inorganic filler mixed in the resin 13.

The above method employs a resin as a material of the substrate 11 so that it is possible to (i) easily form the openings 12 with high accuracy and (ii) prevent the mask substrate 11 from stretching or deflecting due to heat generated under a high temperature condition necessitated during vapor deposition. The mask substrate 11 which is made of the resin 13 also makes it possible to (i) reduce weight of the vapor deposition mask 1 and (ii) prevent the vapor deposition mask 1 from deflecting due to its weight. The method therefore makes it possible to form a vapor-deposited film pattern with high definition.

Furthermore, according to the above method, it is possible to produce the vapor deposition mask 1 in which particles of the inorganic filler are bonded to each other by the resin 13 because the resin material 21 and the inorganic filler are mixed and materials are thus mixed with each other so as to form the mask substrate 11. Therefore, unlike a conventional vapor deposition mask, peeling of a layer will not occur. This does not cause the inorganic filler to separate from the resin 13, and ultimately does not cause the inorganic filler to peel and fall from the resin 13.

The above method therefore makes it possible to provide a method of producing a vapor deposition mask in which a vapor-deposited film pattern is formed with high definition and materials hardly separate from each other.

Furthermore, according to the above method, materials are mixed with each other as has been discussed. It is therefore possible to reduce the number of production steps as compared with the conventional case where one of the resin layer and the metal layer is formed and then the other is formed. This makes it possible to restrain an increase in percent defective due to integration of percent defectives in the respective production steps. This ultimately makes it possible to inexpensively and efficiently produce the vapor deposition masks 1.

According to the above method, it is possible to prepare, in accordance with a kind of the inorganic filler, a vapor deposition mask 1 having properties of the inorganic filler by mixing the inorganic filler in the resin 13.

According to the above method, the materials are first mixed with each other and are then shaped. This makes it possible to freely adjust a proportion of the inorganic filler in the resin 13, and consequently makes it possible to freely adjust properties (e.g., hardness, sturdiness, magnetic strength, and the like) of a resultant vapor deposition mask 1.

The materials are mixed with each other in the vapor deposition mask 1 produced by the above method. It is therefore possible to prevent the vapor deposition mask 1 from warping due to a difference in thermal expansion coefficient between the resin layer and the metal layer, as compared with a case where a metal layer is laminated on a resin layer.

The vapor deposition mask 1 produced by the above method includes no metal layer separately from the resin layer unlike the conventional case. This makes it possible to increase an angle at which the vapor deposition particles can enter, as compared with a conventional vapor deposition mask in which the metal layer is further provided on the resin layer. In a case where the vapor deposition is made with the use of the vapor deposition mask 1, it is possible to improve utilization efficiency of the vapor deposition particles. It is consequently possible to improve an efficiency in mass production.

A method of producing a vapor deposition mask 1 in accordance with a second aspect of the present invention can be configured such that, in the first aspect of the present invention, the inorganic filler is a magnetic filler made of a magnetic substance; and in the step (b), the mixture 20 is poured into the shaping die (reactor 31), and is then shaped while a magnetic field generated by a magnetic field generating source (e.g., coils 32 or magnetic mask 41) is being applied to regions, in the shaping die, other than formation regions of the respective openings 12 of the mask substrate 11 so that the inorganic filler is unevenly distributed in the regions other than the formation regions.

According to the above method, the magnetic force causes the inorganic filler to be unevenly distributed in the regions other than the formation regions. This makes it easier to form the openings 12, with high accuracy, by use of laser processing or the like. This also eliminates waste of the inorganic filler, and therefore allows a reduction in production cost.

A method of producing a vapor deposition mask 1 in accordance with a third aspect of the present invention can be configured such that, in the second aspect of the present invention, in the step (b), the magnetic field is generated so as to surround the formation regions so that the inorganic filler is oriented along the magnetic field so as to surround the openings 12 of the mask substrate 11.

Since the metal flakes made of a metal film are, however, randomly formed, the vapor deposition mask disclosed in Patent Literature 1 has, in the vicinity of an opening (e.g., a region between adjacent openings), (i) a region in which the metal flakes are present and (ii) a region in which no metal flake is present. It is therefore likely that a region exists in which close contact between the film formation target substrate and the vapor deposition mask is insufficient. This causes the vapor deposition mask to partially float, and consequently causes a reduction in accuracy of a vapor deposition pattern.

However, according to the above method, the inorganic filler is oriented along the magnetic field so as to surround the openings 12 of the mask substrate 11. This (i) prevents the vapor deposition mask 1 from floating around the openings 12 and (ii) secures close contact between the film formation target substrate 200 and the vapor deposition mask 1.

The above method therefore makes it possible to make a vapor deposition while the film formation target substrate 200 and the vapor deposition mask 1 are in close contact with each other, particularly around the openings 12. This allows an improvement in accuracy of a vapor deposition pattern.

A method of producing a vapor deposition mask 1 in accordance with a fourth aspect of the present invention can be configured such that, in the third aspect of the present invention, the magnetic field generating source includes coils 32 arranged in a lattice manner; and in the step (b), an electric current is flowed to a coil 32 (coil 32b) surrounding the formation regions, when viewed from above, so that the inorganic filler is oriented along a magnetic field generated by the coil 32 so as to surround the openings 12 of the mask substrate 11.

According to the above method, it is possible for the inorganic filler to be unevenly distributed so as to surround the openings 12, regardless of the number, arrangement, and sizes of the openings 12, by (i) halting supplying of an electric current to the coils 32 (coils 32a), which are located, when viewed from above, in the formation regions of the respective openings 12 and (ii) supplying an electric current to coils 32 (coils 32b), which are located so as to surround corresponding formation regions of the openings 12 and which do not overlap, when viewed from above, with the formation regions of the openings 12.

A method of producing a vapor deposition mask 1 in accordance with a fifth aspect of the present invention can be configured such that, in the second aspect of the present invention, the magnetic field generating source is a magnetic mask 41, made of a magnet or an electric magnet, which is identical in shape to the vapor deposition mask 1 when viewed from above; and in the step (b), a magnetic field, generated by the magnetic mask 41, causes the inorganic filler to be unevenly distributed, when viewed from above, in accordance with a shape of the magnetic mask 41.

According to the above method, it is possible to form the mask substrate 11 in which the inorganic filler is dispersed in a shape substantially identical to a shape of the magnetic mask 41. This makes it easier to form, by the laser processing or the like, the openings 12 with high accuracy. This also eliminates waste of the inorganic filler, and therefore allows a reduction in production cost.

A method of producing a vapor deposition mask 1 in accordance with a sixth aspect of the present invention can be configured to further include the step of, in any one of the first through fifth aspect of the present invention, (c) forming the openings 12 in the mask substrate 11 after the step (b), in the step (c), the openings 12 being formed by use of laser processing.

With the above method, it is easier to form, by the laser processing, the openings 12 with high accuracy, by employing a resin as a material of which the mask substrate 11 is made.

Particularly in a case where, as with the second through fifth aspect of the present invention, the inorganic filler is a magnetic filler and is unevenly distributed in the regions other than the formation regions, heat generated by a laser is not conducted toward the inorganic filler while the openings 12 are being formed by laser processing. This makes it easier to carry out laser processing, and consequently makes it easier to form, by the laser processing, the openings 12 with high accuracy.

A method of producing a vapor deposition mask 1 in accordance with a seventh aspect of the present invention can be configured such that, in any one of the first through fifth aspect of the present invention, the shaping die (reactor 31) has protrusions 51 provided so as to correspond to the respective formation regions; and in the step (b), the mask substrate 11 having the openings 12 is shaped.

According to the above method, the protrusions 51 are provided, on the shaping die, so as to correspond to the respective opening formation regions of the mask substrate. This causes the mixture 20 to be eliminated from the opening formation regions during shaping the mask substrate 11. With the above method, it is therefore possible to shape a mask substrate 11 having openings 12 by shaping the mask substrate 11 with use of the shaping die, without separately carrying out laser irradiation or the like.

A method of producing a vapor deposition mask 1 in accordance with an eighth aspect of the present invention can be configured such that, in the seventh aspect of the present invention, the protrusions 51 are removably provided; and the protrusions 51 are removed after the step (b).

According to the above method, since the protrusions 51 can be removed after shaping the mask substrate 11, it is possible to easily remove the mask substrate 11 from the shaping die.

A method of producing a vapor deposition mask 1 in accordance with a ninth aspect of the present invention can be configured such that, in the seventh through eighths aspects of the present invention, each of the protrusions 51 has a taper shape.

According to the above method, in a case where the protrusions 51 are each provided to have a taper shape, it is possible to form walls of the openings 12 of the mask substrate 11 in a taper shape identical to that of the protrusions 51.

This makes it possible to produce a vapor deposition mask 1 that can more effectively restrain the occurrence of a vapor deposition shadow.

A method of producing a vapor deposition mask 1 in accordance with the tenth aspect of the present invention can be configured such that, in the first through ninth aspects of the present invention, the shaping die (reactor 31) has a groove 31a for forming, along a circumferential part of the mask substrate 11, a support (mask frame 14) for supporting the mask substrate 11; and in the step (b), the mask substrate 11 and the support are monolithically shaped from the mixture 20 so that a vapor deposition mask 1 is formed, along which circumferential part the support is provided.

According to the above method, since the mask substrate 11 and the support are monolithically formed by use of a single material, it is also possible to restrain the occurrence of a thermal stress during vapor deposition. This prevents the vapor deposition mask 1 from deforming. Furthermore, the above method makes it possible to concurrently prepare a mask substrate 11 and the support. It is therefore unnecessary to separately carrying out bonding and/or fixing of the mask substrate 11 and the support. This makes it possible to (i) reduce the number of the production steps and (ii) reduce the time required for producing the vapor deposition mask 1, as compared with a case where the mask substrate 11 and the support are bonded and/or fixed to each other after shaping the mask substrate 11.

A vapor deposition mask 1 in accordance with an eleventh aspect of the present invention can be configured such that, in the tenth aspect of the present invention, in the step (b), the support is shaped while a reinforcing member 5 is being put in the groove 31a.

The above method allows a reduction in time required for shaping the support and an enhancement in strength of the support, and thus prevents the vapor deposition mask 1 from deforming.

A vapor deposition mask 1 in accordance with a twelfth aspect of the present invention includes: a mask substrate 11 having openings 12, each of which causes vapor deposition particles (vapor deposition material 103) to pass therethrough, the mask substrate 11 containing a resin 13 and an inorganic filler mixed in the resin 13.

The above configuration employs a resin as a material of the substrate 11 so that it is possible to (i) easily form the openings 12 with high accuracy and (ii) prevent the mask substrate 11 from stretching or deflecting due to heat generated under a high temperature condition necessitated during vapor deposition. The mask substrate 11 which is made of the resin 13 also makes it possible to (i) reduce weight of the vapor deposition mask 1 and (ii) prevent the vapor deposition mask 1 from deflecting due to its weight. It is therefore possible to form a vapor-deposited film pattern with high definition by using the vapor deposition mask 1.

According to the vapor deposition mask 1, the inorganic filler is mixed in the resin 13 and the materials are thus mixed with each other. Therefore, unlike a conventional vapor deposition mask, peeling of a layer will not occur. This does not cause the inorganic filler to separate from the resin 13, and ultimately does not cause the inorganic filler to peel and fall from the resin 13.

The above configuration therefore makes it possible to provide a vapor deposition mask 1 in which a vapor-deposited film pattern is formed with high definition and materials hardly separate from each other.

Furthermore, according to the vapor deposition mask 1, it is possible to reduce the number of production steps as compared with the conventional case where one of the resin layer and the metal layer is formed and then the other is formed. This makes it possible to restrain an increase in percent defective due to integration of percent defectives in the respective production steps. This ultimately makes it possible to inexpensively and efficiently produce the vapor deposition masks 1.

The organic filler is mixed in the resin 13 in the vapor deposition mask 1. It is therefore possible to prevent the vapor deposition mask 1 from warping due to a difference in thermal expansion coefficient between the resin layer and the metal layer, as compared with a case where a metal layer is laminated on a resin layer.

The vapor deposition mask 1 includes no metal layer separately from the resin layer unlike the conventional case. This makes it possible to increase an angle at which the vapor deposition particles can enter, as compared with a conventional vapor deposition mask in which the metal layer is further provided on the resin layer. In a case where the vapor deposition is made with the use of the vapor deposition mask 1, it is possible to improve utilization efficiency of the vapor deposition particles. It is consequently possible to improve an efficiency in mass production.

A vapor deposition mask 1 in accordance with a thirteenth aspect of the present invention can be configured such that, in the twelfth aspect of the present invention, the inorganic filler is a magnetic filler made of a magnetic substance; and the inorganic filler is unevenly distributed around the openings 12 so as to surround the openings 12.

Since the metal flakes made of a metal film are, however, randomly formed, the vapor deposition mask disclosed in Patent Literature 1 has, in the vicinity of an opening (e.g., a region between adjacent openings), (i) a region in which the metal flakes are present and (ii) a region in which no metal flake is present. It is therefore likely that a region exists in which close contact between the film formation target substrate and the vapor deposition mask is insufficient. This causes the vapor deposition mask to partially float, and consequently causes a reduction in accuracy of a vapor deposition pattern.

However, according to the above configuration, the inorganic filler is unevenly distributed around the openings 12 so as to surround the openings 12. This (i) prevents the vapor deposition mask 1 from floating around the openings 12 and (ii) secures close contact between the film formation target substrate 200 and the vapor deposition mask 1.

The above configuration therefore makes it possible to make a vapor deposition while the film formation target substrate 200 and the vapor deposition mask 1 are in close contact with each other, particularly around the openings 12. This makes it possible to provide the vapor deposition mask which can improve the accuracy of a vapor deposition pattern.

A vapor deposition mask 1 in accordance with the fourteenth aspect of the present invention can be configured such that, in the twelfth or thirteenth aspect of the present invention, the mask substrate 11 has, in a circumferential part, a support (mask frame 14) for supporting the mask substrate 11; and the support is made of a material identical to a material of which the mask substrate 11 is made, and the support and the mask substrate 11 are monolithically shaped.

According to the above configuration, since the mask substrate 11 and the support are monolithically formed by use of a single material, it is also possible to restrain the occurrence of a thermal stress during vapor deposition. This prevents the vapor deposition mask 1 from deforming. Furthermore, the above configuration makes it possible to concurrently prepare a mask substrate 11 and the support. It is therefore unnecessary to separately carrying out bonding and/or fixing of the mask substrate 11 and the support. This makes it possible to (i) reduce the number of the production steps and (ii) reduce the time required for producing the vapor deposition mask 1, as compared with a case where the mask substrate 11 and the support are bonded and/or fixed to each other after shaping the mask substrate 11.

A vapor deposition mask 1 in accordance with a fifteenth aspect of the present invention can be configured such that, in the fourteenth aspect of the present invention, the support (mask frame 14) includes therein a reinforcing member 5 configured to reinforce a strength of the vapor deposition mask 1.

The support which includes the reinforcing member 5 allows a reduction in time required for shaping the support and an enhancement in strength of the support, and thus prevents the vapor deposition mask 1 from deforming.

A vapor deposition device 100 in accordance with a sixteenth aspect of the present invention includes: a vapor deposition mask 1 in accordance with any one of the twelfth through fifteenth aspects of the present invention; and a vapor deposition source 102 configured to emit vapor deposition particles (vapor deposition material 103) toward the openings 12 of the vapor deposition mask 1.

The above configuration therefore makes it possible to provide a vapor deposition device 100 which forms a vapor-deposited film pattern with high definition and which hardly causes the materials from separating from each other.

A method of vapor deposition in accordance with a seventeenth aspect of the present invention is a method of vapor-depositing a film, having a given pattern, on a film formation target substrate 200 by using a vapor deposition mask 1 in accordance with any one of the twelfth through fifteenth aspects of the present invention, the method comprising the steps of: (a) fixing the film formation target substrate 200 and the vapor deposition mask 1 in a state where the film formation target substrate 200 and the vapor deposition mask 1 face each other and providing a vapor deposition source 102, which is configured to emit vapor deposition particles (vapor deposition material 103), so that the vapor deposition source 102 is located on an opposite side to a side of the vapor deposition mask 1 on which side the film formation target substrate 200 is located; and (b) depositing the vapor deposition particles on the film formation target substrate 200 via the openings 12 of the vapor deposition mask 1.

A method of vapor deposition in accordance with an eighteenth aspect of the present invention can be configured such that, in the seventeenth aspect of the present invention, in the step (a), the vapor deposition mask 1, the film formation target substrate 200, and the vapor deposition source are fixed while the film formation target substrate 200 and the vapor deposition mask 1 are being in contact with each other, and in the step (b), the vapor deposition particles are deposited on the film formation target substrate 200 via the openings 12 of the vapor deposition mask 1 while the film formation target substrate 200 and the vapor deposition mask 1 are being in contact with each other.

That is, the method of vapor deposition in accordance with the eighteenth aspect of the present invention is a method of vapor-depositing a film, having a given pattern, on a film formation target substrate 200 by using a vapor deposition mask 1 in accordance with any one of the twelfth through fifteenth aspects of the present invention, the method including the steps of: (a) fixing the film formation target substrate 200 and the vapor deposition mask 1 in a state where the film formation target substrate 200 and the vapor deposition mask 1 are in contact with each other and providing a vapor deposition source 102, which is configured to emit vapor deposition particles (vapor deposition material 103), so that the vapor deposition source 102 is located on an opposite side to a side of the vapor deposition mask 1 on which side the film formation target substrate 200 is located; and (b) depositing the vapor deposition particles on the film formation target substrate 200 via the openings 12 of the vapor deposition mask 1 while the film formation target substrate 200 and the vapor deposition mask 1 are being in contact with each other.

According to the seventeenth aspect or the eighteenth aspect of the present invention, the mask substrate 11 employs, as has been discussed above, a resin as a material of the substrate 11 so that it is possible to (i) easily form the openings 12 with high accuracy and (ii) prevent the mask substrate 11 from stretching or deflecting due to heat generated under a high temperature condition necessitated during vapor deposition. According to the vapor deposition mask 1, the mask substrate 11 which is made of the resin 13 also makes it possible to (i) reduce weight of the vapor deposition mask 1 and (ii) prevent the vapor deposition mask 1 from deflecting due to its weight.

According to the vapor deposition mask 1, the inorganic filler is mixed in the resin 13 and the materials are thus mixed with each other. Therefore, unlike a conventional vapor deposition mask, peeling of a layer will not occur. This does not cause the inorganic filler to separate from the resin 13, and ultimately does not cause the inorganic filler to peel and fall from the resin 13.

The organic filler is mixed in the resin 13 in the vapor deposition mask 1. It is therefore possible to prevent the vapor deposition mask 1 from warping due to a difference in thermal expansion coefficient between the resin layer and the metal layer, as compared with a case where a metal layer is laminated on a resin layer.

The seventeenth aspect or the eighteenth aspect of the present invention therefore makes it possible to form a vapor-deposited film pattern with high definition by making a vapor deposition by using the vapor deposition mask 1.

The vapor deposition mask 1 includes no metal layer separately from the resin layer unlike the conventional case. This makes it possible to increase an angle at which the vapor deposition particles can enter, as compared with a conventional vapor deposition mask in which the metal layer is further provided on the resin layer. In a case where the vapor deposition is made with the use of the vapor deposition mask 1, it is possible to improve utilization efficiency of the vapor deposition particles. It is consequently possible to improve an efficiency in mass production.

According to the method in accordance with an eighteenth aspect of the present invention, by depositing vapor deposition particles on the film formation target substrate 200 via the openings 12 of the vapor deposition mask 1 while the vapor deposition mask 1 and the film formation target substrate 200 are in contact with each other, it is possible to further restrain the occurrence of a vapor deposition shadow. This allows a formation of a higher-definition vapor-deposited film pattern. The eighteenth aspect of the present invention therefore makes it possible to provide a method of deposition that allows a vapor-deposited film pattern to be formed with high definition.

A production device (mask production device 30) for producing a vapor deposition mask 1 in accordance with a nineteenth aspect of the present invention can be a production device for producing a vapor deposition mask 1 including a mask substrate 11 which contains a resin 13 and a magnetic filler (e.g., inorganic particles 3 made of a magnetic substance or inorganic fibers), made of a magnetic substance, mixed in the resin 13 and which has openings 12 each of which allows vapor deposition particles (vapor deposition material 103) to pass therethrough, the production device including a shaping die (reactor 31) and a magnetic field generating source (e.g., coils 32 or magnetic mask 41) which generates a magnetic field in formation regions, in the shaping die, of the respective openings 12.

According to the above production device, when the vapor deposition mask 1 including the mask substrate 11 which contains the resin 13 and a magnetic filler, which is made of a magnetic substance and contained in the resin 13, and which has the openings 12, each of which allows vapor deposition particles to pass therethrough, is to be produced, the magnetic force causes the inorganic filler to be unevenly distributed in the regions other than the formation regions of the respective openings 12.

According to the above production device, by causing the inorganic filler to be unevenly distributed in the regions other than the formation regions, it is possible to form the mask substrate 11 in which the inorganic filler is dispersed in a shape substantially identical to a shape of the magnetic mask 41. This makes it easier to form, by the laser processing or the like, the openings 12 with high accuracy. This also eliminates waste of the inorganic filler, and therefore allows a reduction in production cost.

The above configuration therefore makes it possible to provide a production device suitable for production of the vapor deposition mask 1.

A production device (mask production device 30) for producing a vapor deposition mask 1 in accordance with a twentieth aspect of the present invention can be configured such that, in the nineteenth aspect of the present invention, the magnetic field generating source includes coils 32 arranged in a lattice manner; and an electric current is flowed to a coil 32 surrounding the formation regions, when viewed from above, so that the magnetic filler is oriented along a magnetic field generated by the coil 32 so as to surround the openings 12 of the mask substrate 11.

According to the above configuration, it is possible for the inorganic filler to be unevenly distributed so as to surround the openings 12, regardless of the number, arrangement, and sizes of the openings 12, by (i) halting supplying of an electric current to the coils 32 (coils 32a), which are located, when viewed from above, in the formation regions of the respective openings 12 and (ii) supplying an electric current to coils 32 (coils 32b), which are located so as to surround corresponding formation regions of the openings 12 and which do not overlap, when viewed from above, with the formation regions of the openings 12. The above configuration therefore makes it possible to provide a mask production device 30 which is applicable to production of various vapor deposition masks 1.

7 A production device (mask production device 30) for producing a vapor deposition mask 1 in accordance with a twenty-first aspect of the present invention can be configured such that, in the nineteenth aspect of the present invention, the magnetic field generating source is a magnetic mask 41, made of a magnet or an electric magnet, which is identical in shape to the vapor deposition mask 1 when viewed from above; and a magnetic field, generated by the magnetic mask 41, causes the magnetic filler to be unevenly distributed, when viewed from above, in accordance with a shape of the magnetic mask 1.

According to the above production device, it is possible to form the mask substrate 11 in which the inorganic filler is dispersed in a shape substantially identical to a shape of the magnetic mask 41. This makes it easier to form, by the laser processing or the like, the openings 12 with high accuracy. This also eliminates waste of the inorganic filler, and therefore allows a reduction in production cost.

A production device (mask production device 30) for producing a vapor deposition mask 1 in accordance with a twenty-second aspect of the present invention can include (i) a mask substrate 11 which contains a resin 13 and an inorganic filler mixed in the resin 13 and which has openings 12 each of which allows vapor deposition particles (vapor deposition material 103) to pass therethrough and (ii) a shaping die (reactor 31) on which removable protrusions 51 are provided so as to correspond to formation regions of the respective openings 12 of the mask substrate 11.

According to the above configuration, the protrusions 51 are provided, on the shaping die, so as to correspond to the respective opening formation regions of the mask substrate. This causes the material (mixture 20), from which the mask substrate 11 is formed, to be eliminated from the opening formation regions during shaping the mask substrate 11. With the above configuration, it is therefore possible to shape a mask substrate 11 having openings 12 by shaping the mask substrate 11 with use of the shaping die, without separately carrying out laser irradiation or the like. The above configuration also eliminates waste of the inorganic filler, and therefore allows a reduction in production cost.

According to the above configuration, since the protrusions 51 can be removed after shaping the mask substrate 11, it is possible to easily remove the mask substrate 11 from the shaping die.

The above production device makes it possible to easily produce the vapor deposition mask 1 which includes the mask substrate 11, which contains the resin 13 and the inorganic filler mixed in the resin 13, and which has openings 12, each of which allows vapor deposition particle to pass therethrough.

The above configuration therefore makes it possible to provide a production device suitable for production of the vapor deposition mask 1.

A production device (mask production device 30) for producing a vapor deposition mask 1 in accordance with a twenty-third aspect of the present invention can be configured such that, in any one of the nineteenth through twenty-second aspects of the present invention, the shaping die (reactor 31) has a groove 31a for forming, along a circumferential part of the mask substrate 11, a support (mask frame 14) for supporting the mask substrate 11.

The above configuration makes it possible to concurrently and monolithically form the mask substrate 11 and the support by use of a single material. This makes it possible to restrain the occurrence of a thermal stress during vapor deposition. The above configuration therefore makes it possible to provide the production device for producing a vapor deposition mask which production device can (i) prevent the vapor deposition mask 1 from deforming, (ii) reduce the number of the production steps, and (iii) reduce the time required for producing the vapor deposition mask 1, as compared with a case where the mask substrate 11 and the support are bonded and/or fixed to each other after shaping the mask substrate 11.

The present invention is not limited to the embodiments, but can be altered by a skilled person in the art within the scope of the claims. An embodiment derived from a proper combination of technical means each disclosed in a different embodiment is also encompassed in the technical scope of the present invention. Further, it is possible to form a new technical feature by combining the technical means disclosed in the respective embodiments.

The present invention is applicable to (i) a vapor deposition mask that can be suitably applied to production of, for example, an organic EL element, an inorganic EL element, an organic EL display device including the organic EL element, and an inorganic EL display device including the inorganic EL element, (ii) a vapor deposition device, (iii) a method of producing the vapor deposition mask, and (iv) a production device for producing the vapor deposition mask.

### REFERENCE SIGNS LIST

1: Vapor deposition mask
2: Resin layer
3: Inorganic particle (inorganic filler)
5: Reinforcing member
11: Mask substrate
12: Opening (opening in mask substrate, opening in vapor deposition mask)
13: Resin
14: Mask frame (support)
20: Mixture
21: Resin material
30: Mask production device
31: Reactor (shaping die)
31a: Groove
32, 32a, 32b: Coil
32A, 32B: Coil column
33: Coil holding member
41: Magnetic mask (magnetic field generating source)
42: Opening (opening in magnetic mask)
51: Protrusion
100: Vapor deposition device
101: Magnetic force generating source
102: Vapor deposition source
102a: Emission hole
103: Vapor deposition material (vapor deposition particle)
200: Film formation target substrate
201: Film formation target surface
210: Vapor deposition film

1. A method of producing a vapor deposition mask including a mask substrate having openings, each of which causes vapor deposition particles to pass therethrough, the method comprising the steps of:
(a) preparing a mixture which contains a resin material and an inorganic filler; and
(b) shaping, with use of a shaping die, the mixture so that the mask substrate is shaped, the mask substrate containing (i) a resin made of the resin material and (ii) the inorganic filler mixed in the resin.

2. The method of claim 1, wherein:
the inorganic filler is a magnetic filler made of a magnetic substance; and
in the step (b), the mixture is poured into the shaping die, and is then shaped while a magnetic field generated by a magnetic field generating source is being applied to regions, in the shaping die, other than formation regions of the respective openings of the mask substrate so that the inorganic filler is unevenly distributed in the regions other than the formation regions.

3. The method of claim 2, wherein:
in the step (b), the magnetic field is generated so as to surround the formation regions so that the inorganic filler is oriented along the magnetic field so as to surround the openings of the mask substrate.

4. The method of claim 3, wherein:
the magnetic field generating source includes coils arranged in a lattice manner; and
in the step (b), an electric current is flowed to a coil surrounding the formation regions, when viewed from above, so that the inorganic filler is oriented along a magnetic field generated by the coil so as to surround the openings of the mask substrate.

5. The method of claim 2, wherein:
the magnetic field generating source is a magnetic mask, made of a magnet or an electric magnet, which is identical in shape to the vapor deposition mask when viewed from above; and
in the step (b), a magnetic field, generated by the magnetic mask, causes the inorganic filler to be unevenly distributed, when viewed from above, in accordance with a shape of the magnetic mask.

6. The method of claim 1, further comprising the step of:
(c) forming the openings in the mask substrate after the step (b),
in the step (c), the openings being formed by use of laser processing.

7. The method of claim 1, wherein:
the shaping die has protrusions provided so as to correspond to the respective formation regions; and
in the step (b), the mask substrate having the openings is shaped.

8. The method of claim 7, wherein:
the protrusions are removably provided; and
the protrusions are removed after the step (b).

9. The method of claim 7, wherein:
each of the protrusions has a taper shape.

10. The method of claim 1, wherein:
the shaping die has a groove for forming, along a circumferential part of the mask substrate, a support for supporting the mask substrate; and
in the step (b), the mask substrate and the support are monolithically shaped from the mixture so that a vapor deposition mask is formed, along which circumferential part the support is provided.

11. The method of claim 10, wherein:
in the step (b), the support is shaped while a reinforcing member is being put in the groove.

12. A vapor deposition mask, comprising:
a mask substrate having openings, each of which causes vapor deposition particles to pass therethrough,
the mask substrate containing a resin and an inorganic filler mixed in the resin.

13. The vapor deposition mask of claim 12, wherein:
the inorganic filler is a magnetic filler made of a magnetic substance; and
the inorganic filler is unevenly distributed around the openings so as to surround the openings.

14. The vapor deposition mask of claim 12, wherein:
the mask substrate has, in a circumferential part, a support for supporting the mask substrate; and
the support is made of a material identical to a material of which the mask substrate is made, and the support and the mask substrate are monolithically shaped.

15. The vapor deposition mask of claim 14, wherein:
the support includes therein a reinforcing member configured to reinforce a strength of the vapor deposition mask.

16. A vapor deposition device, comprising:
a vapor deposition mask of claim 12; and
a vapor deposition source configured to emit vapor deposition particles toward the openings of the vapor deposition mask.

17. A method of vapor-depositing a film, having a given pattern, on a film formation target substrate by using a vapor deposition mask of claim 12, the method comprising the steps of:
(a) fixing the film formation target substrate and the vapor deposition mask in a state where the film formation target substrate and the vapor deposition mask are in contact with each other and providing a vapor deposition source, which is configured to emit vapor deposition particles, so that the vapor deposition source is located on an opposite side to a side of the vapor deposition mask on which side the film formation target substrate is located; and
(b) depositing the vapor deposition particles on the film formation target substrate via the openings of the vapor deposition mask while the film formation target substrate and the vapor deposition mask are being in contact with each other.
